(19) United States
(12) Patent Application Publication
(10) Pub. No.: US 2026/0344192 A1
(43) Pub. Date: Oct. 29, 2026

(54) ELECTRONIC DEVICE AND MANUFACTURING METHOD FOR THE SAME

(71) Applicant: Samsung Display Co., Ltd., Yongin-si (KR)

(72) Inventors: Bogeon JEON, Yongin-si (KR); Jungi KIM, Yongin-si (KR); Jin-Lak KIM, Yongin-si (KR); Hye Sun KIM, Yongin-si (KR)

(73) Assignee: Samsung Display Co., Ltd., Yongin-si (KR)

(21) Appl. No.: 19/633,355

(22) Filed: Mar. 30, 2026

(30) Foreign Application Priority Data
Apr. 28, 2025 (KR) 10-2025-0055473

(51) Int. Cl. H10K 59/122; H10K 59/12; H10K 59/121; H10K 59/123; H10K 59/124; H10K 59/131

(52) U.S. Cl. CPC H10K 59/122; H10K 59/1201; H10K 59/1213; H10K 59/123; H10K 59/124; H10K 59/131

(57) ABSTRACT

An electronic device including a display panel having a circuit element layer including a power line, an organic insulating layer on the power line and a transistor, and a first conductive pattern spaced from the transistor and connected to the power line, a pixel defining layer on the circuit element layer and forming emission and contact openings spaced apart, a light-emitting element on the circuit element layer and including a first electrode electrically connected to the transistor and exposed by the emission opening, an intermediate layer, and a second electrode, a second conductive pattern between the organic insulating and pixel defining layers, the second conductive pattern being apart from the first electrode and exposed by the contact opening, and the second conductive pattern connecting to the first conductive pattern, and a partition wall in the contact opening and connecting the second electrode to the second conductive pattern.

### CROSS-REFERENCE TO RELATED APPLICATION

This U.S. non-provisional patent application claims priority under 35 U.S.C. § 119 to Korean Patent Application No. 10-2025-0055473, filed on Apr. 28 2025, the entire contents of which are hereby incorporated by reference.

### BACKGROUND

The present disclosure herein relates to an electronic device and a method for manufacturing the same, and more particularly, to an electronic device having improved process efficiency and a method for manufacturing the same.

Generally, electronic apparatuses that provide a user with an image, such as smart phones, digital cameras, laptop computers, navigation units, and smart televisions, include an electronic device for displaying the image. The electronic device generates an image and provides the generated image to the user through a display screen.

The electronic device includes a plurality of pixels for generating images and a plurality of lines connected to the pixels. The pixels receive driving signals through the lines and are driven accordingly.

In a medium-to large-sized electronic device having an enlarged display area, such as a tablet or a smart television, differences in driving voltages delivered to the pixels may occur.

### SUMMARY

The present disclosure provides an electronic device in which a voltage drop phenomenon is prevented (or reduced) and a uniform (or similar) voltage is supplied to the pixels (e.g., by compensating for differences in driving voltages).

The present disclosure also provides a method for manufacturing an electronic device in which the process is simplified and process efficiency is improved.

Embodiments of the inventive concepts provide an electronic device including a window module, and a display panel, the window module being on the display panel, and the display panel including a base substrate, a circuit element layer including a power line on the base substrate, an organic insulating layer on the power line, a transistor between the base substrate and the organic insulating layer, and a first conductive pattern spaced apart from the transistor and connected to the power line, a pixel defining layer on the circuit element layer, the pixel defining layer forming an emission opening and a contact opening spaced apart from the emission opening, a light-emitting element on the circuit element layer, the light-emitting element including a first electrode electrically connected to the transistor and at least partially exposed by the emission opening, a second electrode on the first electrode, and an intermediate layer between the first electrode and the second electrode, a second conductive pattern between the organic insulating layer and the pixel defining layer, the second conductive pattern being spaced apart from the first electrode and at least partially exposed by the contact opening, and the second conductive pattern penetrating through the organic insulating layer and connecting to the first conductive pattern, and a partition wall including a first partition wall in the contact opening and connecting the second electrode to the second conductive pattern.

In embodiments, the partition wall may include a second partition wall overlapping the pixel defining layer, and the first partition wall and the second partition wall may be connected to each other to have an integrated shape.

In embodiments, a side surface of the partition wall may include at least one first tip.

In embodiments, the partition wall may include a first partition wall layer and a second partition wall layer on the first partition wall layer, and the at least one first tip may be defined by a side surface of the second partition wall layer that protrudes from a side surface of the first partition wall layer.

In embodiments, the partition wall may include a third partition wall layer below the first partition wall layer.

In embodiments, the first partition wall layer may be conductive.

In embodiments, the intermediate layer may be spaced apart from the second partition wall layer in a planar view.

In embodiments, the second electrode may be in contact with the first partition wall layer.

In embodiments, the partition wall may include a protective layer between the pixel defining layer and the first partition wall layer.

In embodiments, a side surface of the protective layer may include at least one second tip.

In embodiments, the protective layer may include a first protective layer, a second protective layer, and a third protective layer sequentially laminated, and the at least one second tip may be defined by a side surface of the third protective layer that protrudes from a side surface of the first protective layer or a side surface of the second protective layer.

In embodiments, the first protective layer may include a metal oxide, and the second protective layer and the third protective layer may include insulating materials.

In embodiments, the electronic device may further include at least one of a processor, a memory, or a power module.

In embodiments, the electronic device may be a television, a monitor, an outdoor signboard, a personal computer, a notebook computer, a personal digital terminal, an automotive instrument panel, a center fascia, a navigation device, a room mirror display, a game console, a smartphone, a tablet, a smart watch, smart glasses, a head-mounted display, or a camera.

In embodiments of the inventive concepts, an electronic device includes a window module, and a display panel, the window module being on the display panel, and the display panel including a base substrate, a circuit element layer including a power line on the base substrate, an organic insulating layer on the power line, a transistor between the base substrate and the organic insulating layer, and a first conductive pattern spaced apart from the transistor and connected to the power line, a pixel defining layer on the circuit element layer, the pixel defining layer forming an emission opening and a contact opening spaced apart from the emission opening, and the pixel defining layer including a base layer in which the emission opening and the contact opening are defined, and a protrusion spaced apart from the emission opening in a planar view and protruding upward from the base layer, a light-emitting element on the circuit element layer, the light-emitting element including a first electrode electrically connected to the transistor and at least partially exposed by the emission opening, a second electrode on the first electrode, and an intermediate layer between the first electrode and the second electrode, and a partition wall in the contact opening and electrically connecting the first conductive pattern to the second electrode, the partition wall being on the base layer, and a top surface of the partition wall being spaced apart from a top surface of the protrusion in the planar view.

In embodiments, the base layer and the protrusion may have an integrated shape.

In embodiments, the electronic device may further include a second conductive pattern at a same layer as the first electrode, the second conductive pattern may be connected to the partition wall through the contact opening and penetrates through the organic insulating layer to connect to the first conductive pattern.

In embodiments of the inventive concepts, a method for manufacturing an electronic device includes forming a transistor on a base substrate, forming a first conductive pattern on the transistor, forming a first organic insulating layer on the first conductive pattern, forming a contact hole in the first organic insulating layer to expose at least a portion of the first conductive pattern, forming a second conductive pattern and a first electrode on the first organic insulating layer, the second conductive pattern being connected to the first conductive pattern through the contact hole, and the first electrode being spaced apart from the second conductive pattern, applying an organic material on the first organic insulating layer to form an initial pixel defining layer, forming a pixel defining layer using a halftone mask on the initial pixel defining layer, the pixel defining layer including a base layer and a protrusion, forming a plurality of conductive layers on the pixel defining layer, etching the conductive layers to form a partition wall, depositing an intermediate layer on the first electrode, and depositing a second electrode on the intermediate layer.

In embodiments, the etching of the plurality of conductive layers may include dry etching and wet etching, and at least one tip may be formed on a side surface of the partition wall by the wet etching.

In embodiments, the method for manufacturing the electronic device may further include forming a second organic insulating layer covering the transistor, the forming of the first conductive pattern may include forming the first conductive pattern on the second organic insulating layer.

### BRIEF DESCRIPTION OF THE FIGURES

The accompanying drawings are included to provide a further understanding of the inventive concepts, and are incorporated in and constitute a part of this specification. The drawings illustrate embodiments of the inventive concepts and, together with the description, serve to explain principles of the inventive concepts. In the drawings:

FIG. 1 is a block diagram of an electronic device according to embodiments of the inventive concepts;

FIG. 2 is schematic views of various electronic devices according to embodiments of the inventive concepts;

FIG. 3 is a perspective view of an electronic device according to embodiments of the inventive concepts;

FIG. 4 is a cross-sectional view of the electronic device according to embodiments of the inventive concepts;

FIG. 5 is a cross-sectional view of a display panel according to embodiments of the inventive concepts;

FIG. 6A is a block diagram of a display module according to embodiments of the inventive concepts;

FIG. 6B is an equivalent circuit diagram of a pixel according to embodiments of the inventive concepts;

FIGS. 7A and 7B are plan views of a pixel defining layer according to embodiments of the inventive concepts;

FIGS. 8A and 8B are cross-sectional views taken along line I-I′ of FIG. 7B;

FIG. 9 is an enlarged view of the display panel according to embodiments of the inventive concepts;

FIGS. 10A to 10D are enlarged views of the display panel according to embodiments of the inventive concepts; and

FIGS. 11A to 11M are cross-sectional views illustrating a method for manufacturing a display panel according to embodiments of the inventive concepts.

### DETAILED DESCRIPTION

In this specification, it will also be understood that when one component (or region, layer, portion) is referred to as being ‘on’, ‘connected to’, or ‘coupled to’ another component, it may be directly disposed/connected/coupled on/to the one component, or an intervening third component may also be present.

Like reference numerals refer to like elements throughout. Also, in the figures, the thickness, ratio, and dimensions of components are exaggerated for clarity of illustration. The term “and/or” includes any and all combinations of one or more of the associated components.

The terms such as first and second may be used to describe various components, but the components should not be limited by these term. The terms are used solely for the purpose of distinguishing one component from another. For example, a first element referred to as a first element in an example may be referred to as a second element in another example without departing from the scope of the appended claims. The singular forms include the plural forms as well, unless the context clearly indicates otherwise.

Also, “under”, “below”, “above', “upper”, and the like are used for explaining relation association of components illustrated in the drawings. The terms may be a relative concept and described based on directions expressed in the drawings. For example, if the device in the drawings is turned over, components described as “below” or “beneath” other components or features would then be oriented “above” the other components or features. Thus, the term “below” may encompass both an orientation of above and below. The device may be otherwise oriented (rotated 90 degrees or at other orientations) and the spatially relative descriptors used herein interpreted accordingly.

It will be understood that the term “include” or “comprise”, when used in this specification, specifies the presence of stated features, integers, operations, elements, components, or a combination thereof, but does not preclude the presence or addition of one or more other features, integers, operations, elements, components, or combinations thereof.

Unless otherwise defined, all terms (including technical and scientific terms) used herein have the same meaning as, or a similar meaning to, that commonly understood by a person of ordinary skill in the art to which the inventive concepts belong. In addition, terms such as those defined in commonly used dictionaries should be interpreted as having meanings consistent with their meanings in the context of the relevant technology, and unless explicitly defined, it should not be interpreted in an overly idealistic or overly formal sense.

Hereinafter, embodiments of the inventive concepts are described with reference to the drawings.

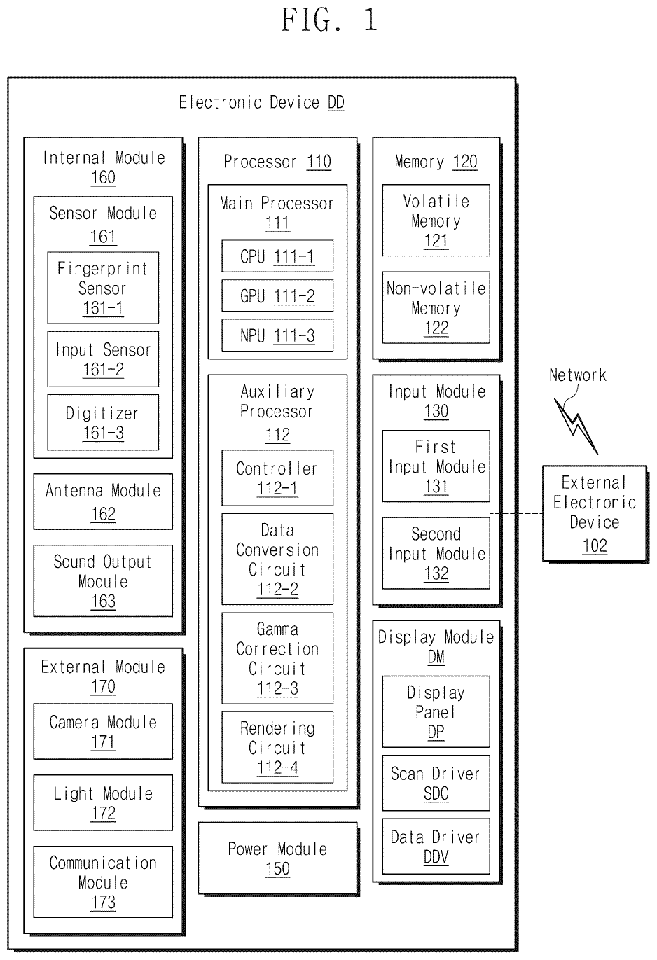

FIG. 1 is a block diagram of an electronic device according to embodiments of the inventive concepts.

FIG. 1 is a block diagram of an electronic device DD according to embodiments. Referring to FIG. 1, an electronic device DD may output various information through a display module DM within an operating system. When a processor 110 executes an application stored in a memory 120, the display module DM may provide application information to a user through a display panel DP.

The processor 110 may acquire external input through an input module 130 or a sensor module 161 and execute an application corresponding to the external input. For example, when a user selects a camera icon displayed on the display panel DP, the processor 110 may acquire a user input through an input sensor 161-2 and activate a camera module 171. The processor 110 may transmit image data corresponding to a captured image obtained through the camera module 171 to the display module DM. The display module DM may display an image corresponding to the captured image through the display panel DP.

As another example, when personal authentication is performed by the display module DM, a fingerprint sensor 161-1 may acquire input fingerprint information as input data. The processor 110 may compare the input data obtained through the fingerprint sensor 161-1 with authentication data stored in the memory 120 and may execute an application based on the comparison result. The display module DM may display information executed according to the application logic through the display panel DP.

As another example, when a music streaming icon displayed on the display module DM is selected, the processor 110 may acquire a user input through the input sensor 161-2 and may activate a music streaming application stored in the memory 120. When a music playback command is input to the music streaming application, the processor 110 may activate a sound output module 163 to provide audio information corresponding to the playback command to the user.

As described above, the operation of the electronic device DD was briefly explained. Hereinafter, the configuration of the electronic apparatus DD will be described in detail. Some of the configurations of the electronic apparatus DD described below may be integrated into a single configuration, or a single configuration may be divided into two or more configurations.

Referring to FIG. 1, the electronic device DD may communicate with an external electronic device 102 via a network (e.g., a short-range wireless communication network or a long-range wireless communication network). According to embodiments, the electronic apparatus DD may include a processor 110, a memory 120, an input module 130, a display module DM, a power module 150, an internal module 160, and/or an external module 170. According to embodiments, at least one of the above-described components of the electronic apparatus DD may be omitted, or one or more other components may be added. According to embodiments, some of the aforementioned components, such as a sensor module 161, an antenna module 162, and/or a sound output module 163, may be integrated into another component, such as the display module DM.

The processor 110 may execute software to control at least one other component (e.g., a hardware or software component) of the electronic device DD connected to the processor 110 and may perform various data processing or computations. According to embodiments, as at least part of the data processing or calculations, the processor 110 may store commands or data, which is received from other components, such as the input module 130, the sensor module 161, and/or a communication module 173, in a volatile memory 121, and process the commands or data stored in the volatile memory 121. The resulting data may be stored in a non-volatile memory 122.

The processor 110 may include a main processor 111 and/or an auxiliary processor 112. The main processor 111 may include at least one of a central processing unit 111-1 (CPU) or an application processor (AP). The main processor 111 may further include at least one of a graphic processing unit 111-2 (GPU), a communication processor (CP), and/or an image signal processor (ISP). The main processor 111 may further include a neural processing unit 111-3 (NPU). The neural processing unit may be a processor specialized in processing artificial intelligence models, and the artificial intelligence model may be generated through machine learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), or a deep Q-network, or a combination of two or more of the above, but may not be limited thereto. The artificial intelligence model may include a software structure, in addition to or instead of a hardware structure. At least two of the aforementioned processing units and processors may be implemented as a single integrated configuration (e.g., a single chip) or as separate configurations (e.g., a plurality of chips).

The auxiliary processor 112 may include a controller 112-1. The controller 112-1 may include an interface conversion circuit and/or a timing control circuit. The controller 112-1 may receive an image signal from the main processor 111, convert data format of the image signal to match the interface specifications of the display module DM, and output the image data. The controller 112-1 may output various control signals necessary (or otherwise, used) for driving the display module DM.

The auxiliary processor 112 may further include a data conversion circuit 112-2, a gamma correction circuit 112-3, and/or a rendering circuit 112-4. The data conversion circuit 112-2 may receive image data from the controller 112-1 and compensate the image data to display images at a desired brightness according to the characteristics of the electronic apparatus DD or user settings, or may convert the image data to reduce power consumption or compensate for afterimages. The gamma correction circuit 112-3 may convert image data or a gamma reference voltage to provide the image displayed on the electronic apparatus DD with a desired gamma characteristic. The rendering circuit 112-4 may receive the image data from the controller 112-1 and render the image data considering the pixel arrangement of the display panel DP applied to the electronic apparatus DD. At least one of the data conversion circuit 112-2, the gamma correction circuit 112-3, or the rendering circuit 112-4 may be integrated into another component, such as the main processor 111 or the controller 112-1. At least one of the data conversion circuit 112-2, the gamma correction circuit 112-3, or the rendering circuit 112-4 may also be integrated into a data driver DDV described below.

The memory 120 may store various data, such as input data or output data related to commands, which are used by at least one component of the electronic apparatus DD, such as the processor 110 or the sensor module 161. The memory 120 may include at least one of a volatile memory 121 and a non-volatile memory 122.

The input module 130 may receive a command or data to be used by a component (e.g., the processor 110, the sensor module 161, or the sound output module 163) of the electronic device DD from an external source (e.g., a user or an external electronic device 102).

The input module 130 may include a first input module 131 that may receive a command or data from the user and/or a second input module 132 that may receive a command or data from the external electronic device 102. The first input module 131 may include a microphone, a mouse, a keyboard, a key (e.g., a button), or a pen (e.g., a passive pen or an active pen). The second input module 132 may support a specified protocol that may be connected to the external electronic device 102 via a wired or wireless connection. According to embodiments, the second input module 132 may include an HDMI (high definition multimedia interface), a USB (universal serial bus) interface, an SD card interface, or an audio interface. The second input module 132 may include a connector that may be physically connected to the external electronic device 102, such as an HDMI connector, a USB connector, an SD card connector, or an audio connector (e.g., a headphone connector).

The display module DM may provide visual information to the user. The display module DM may include a display panel DP, a scan driver SDC, and/or a data driver DDV. The display module DM may further include a window module that may protect the display panel DP, a chassis, and/or a bracket.

The display panel DP may be a liquid crystal display panel, an organic light-emitting display panel, or an inorganic light-emitting display panel, and the type of the display panel DP will not be particularly limited. The display panel DP may be a rigid type or a flexible type that may be rollable or foldable. The display module DM may further include a supporter that may support the display panel DP, a bracket, or a heat dissipation member.

The scan driver SDC may be mounted on the display panel DP as a driving chip. Alternatively, the scan driver SDC may be integrated into the display panel DP. For example, the scan driver SDC may include an amorphous silicon thin-film transistor (TFT) gate driver circuit (ASG), a low-temperature polycrystalline silicon TFT gate driver circuit (LTPS), or an oxide semiconductor TFT gate driver circuit (OSG), which may be embedded in the display panel DP. The scan driver SDC may receive control signals from a controller 112-1 and may output scan signals to the display panel DP in response to the control signals.

The display panel DP may further include a light-emission driver. The light-emission driver may output a light-emission control signal to the display panel DP in response to the control signals received from the controller 112-1. The light-emission driver may be provided separately from or may be integrated with the scan driver SDC.

The data driver DDV may receive control signals from the controller 112-1, may convert image data into analog voltages (e.g., data voltages), and may output the data voltages to the display panel DP in response to the control signals.

The data driver DDV may be integrated with another component, such as the controller 112-1. The interface conversion circuit and the timing control circuit of the controller 112-1 may be integrated into the data driver DDV.

The display module DM may further include the light-emission driver and/or a voltage generation circuit. The voltage generation circuit may output various voltages that may be required (or otherwise, used) to drive the display panel DP.

The power module 150 may supply power to the components of the electronic device DD. The power module 150 may include a battery that may store a power voltage. The battery may include a primary battery that may not be rechargeable, a secondary battery that may be rechargeable, or a fuel cell. The power module 150 may include a power management integrated circuit (PMIC). The PMIC may supply optimized (or appropriate) power to each of the above modules and the modules described below. The power module 150 may include a wireless power transmission/reception member that may be electrically connected to the battery. The wireless power transmission/reception member may include a plurality of antenna radiators in the form of a coil.

The electronic device DD may further include an internal module 160 and/or an external module 170. The internal module 160 may include a sensor module 161, an antenna module 162, and/or a sound output module 163. The external module 170 may include a camera module 171, a light module 172, and/or a communication module 173.

The sensor module 161 may detect input from a user's body or from a pen included in the first input module 131, and may generate an electrical signal or data value corresponding to the input. The sensor module 161 may include at least one of a fingerprint sensor 161-1, an input sensor 161-2, and/or a digitizer 161-3.

The fingerprint sensor 161-1 may generate a data value corresponding to a user's fingerprint. The fingerprint sensor 161-1 may include either an optical-type or a capacitive-type fingerprint sensor.

The input sensor 161-2 may generate a data value corresponding to coordinate information of an input by the user's body or by a pen. The input sensor 161-2 may generate a data value based on a change in capacitance caused by the input. The input sensor 161-2 may detect an input by a passive pen or may transmit and receive data with an active pen.

The input sensor 161-2 may also measure biometric signals such as blood pressure, moisture, or body fat. For example, when a user brings a part of the body into contact with a sensor layer or sensing panel and maintains that position without movement for a certain period of time, the input sensor 161-2 may detect a change in electric field caused by the body part and may detect biometric signals based on the change, thereby outputting information desired by the user to the display module DM.

The digitizer 161-3 may generate a data value corresponding to coordinate information of an input by a pen. The digitizer 161-3 may generate a data value based on a change in electromagnetic field caused by the input. The digitizer 161-3 may detect an input by a passive pen or may transmit and receive data with an active pen.

At least one of the fingerprint sensor 161-1, the input sensor 161-2, and/or the digitizer 161-3 may be implemented as a sensor layer provided on the display panel DP through a continuous process. The fingerprint sensor 161-1, the input sensor 161-2, and/or the digitizer 161-3 may be disposed on an upper side of the display panel DP, and one of them, for example, the digitizer 161-3, may be disposed on a lower side of the display panel DP.

At least two of the fingerprint sensor 161-1, the input sensor 161-2, and/or the digitizer 161-3 may be integrally provided as a single sensing panel through a common process. When integrated as a single sensing panel, the sensing panel may be disposed between the display panel DP and a window module disposed at an upper side of the display panel DP. According to embodiments, the sensing panel may be disposed on the window module, and the position of the sensing panel may not be particularly limited.

At least one of the fingerprint sensor 161-1, the input sensor 161-2, and/or the digitizer 161-3 may be embedded in the display panel DP. That is, at least one of the fingerprint sensor 161-1, the input sensor 161-2, and/or the digitizer 161-3 may be simultaneously (or contemporaneously) provided through a process for forming elements (e.g., light-emitting elements, transistors, etc.) included in the display panel DP.

In addition, the sensor module 161 may generate an electrical signal or data value corresponding to an internal or external state of the electronic device DD. The sensor module 161 may further include, for example, a gesture sensor, a gyro sensor, a pressure sensor, a magnetic sensor, an acceleration sensor, a grip sensor, a proximity sensor, a color sensor, an IR (infrared) sensor, a biosensor, a temperature sensor, a humidity sensor, an illuminance sensor, etc.

The antenna module 162 may include one or more antennas for transmitting or receiving a signal or power to/from the outside (e.g., outside of the electronic device DD). According to embodiments, the communication module 173 may transmit a signal to or receive a signal from the external electronic device 102 through an antenna suitable for a communication scheme. An antenna pattern of the antenna module 162 may be integrated with one component of the display module DM (e.g., the display panel DP) or the input sensor 161-2.

The sound output module 163 may be a device for outputting an audio signal to the outside of the electronic device DD, and may include, for example, a speaker used for general purposes such as multimedia playback or voice playback, and a receiver used exclusively for telephone calls. According to embodiments, the receiver may be integrated with or separately formed from the speaker. An audio output pattern of the sound output module 163 may be integrated with the display module DM.

The camera module 171 may capture still images and moving images. According to embodiments, the camera module 171 may include one or more lenses, an image sensor, or an image signal processor. The camera module 171 may further include an infrared camera capable of detecting user presence, user location, and/or user gaze.

The light module 172 may provide light. The light module 172 may include a light-emitting diode or a xenon lamp. The light module 172 may operate in conjunction with or independently of the camera module 171.

The communication module 173 may support establishment of a wired or wireless communication channel between the electronic device DD and the external electronic device 102, and may perform communication through the established channel. The communication module 173 may include one or all of a wireless communication module such as a cellular communication module, a short-range wireless communication module, or a GNSS (global navigation satellite system) communication module, and/or a wired communication module such as a LAN (local area network) communication module or a power line communication module. The communication module 173 may communicate with the external electronic device 102 via a short-range communication network such as Bluetooth, WiFi Direct, or IrDA (infrared data association), or via a long-range communication network such as a cellular network, the Internet, or a computer network (e.g., LAN or WAN). The above-described various communication modules 173 may be implemented on a single chip or on separate chips.

The input module 130, the sensor module 161, and/or the camera module 171 may be used in conjunction with the processor 110 to control the operation of the display module DM.

The processor 110 may output commands or data to the display module DM, the sound output module 163, the camera module 171, or the light module 172 based on input data received from the input module 130. For example, the processor 110 may generate image data in response to input data applied via a mouse or an active pen and may output the image data to the display module DM. Alternatively, the processor 110 may generate command data corresponding to the input data and may output the command data to the camera module 171 or the light module 172. When no input data is received from the input module 130 for a period of time, the processor 110 may switch the operation mode of the electronic device DD to a low-power mode or a sleep mode, thereby reducing power consumption in the electronic device DD.

The processor 110 may output a command or data to the display module DM, the sound output module 163, the camera module 171, or the light module 172 on the basis of sensing data received from the sensor module 161. For example, the processor 110 may compare authentication data acquired by the fingerprint sensor 161-1 with authentication data stored in the memory 120 and may execute an application based on the comparison result. The processor 110 may execute a command or may output image data to the display module DM based on sensing data detected by the input sensor 161-2 or the digitizer 161-3. When the sensor module 161 includes a temperature sensor, the processor 110 may receive temperature data measured by the sensor module 161 and may perform luminance correction on the image data based on the temperature data.

The processor 110 may receive measurement data regarding user presence, user position, or user gaze from the camera module 171. The processor 110 may perform luminance correction on the image data based on the measurement data. For example, a processor 110, which determines user presence based on input from a camera module 171, may output image data of which the luminance is corrected through the data conversion circuit 112-2 or the gamma correction circuit 112-3, to a display module DM.

Each of the components discussed above (e.g., those illustrated in FIG. 1) may be connected (e.g., a data connection, electrical connection, etc.) to some or all of the other components discussed above (e.g., those illustrated in FIG. 1). For example, some of the above components may be connected to each other via a peripheral communication scheme such as a bus, GPIO (general purpose input/output), SPI (serial peripheral interface), MIPI (mobile industry processor interface), or UPI (ultra path interconnect) link and may exchange signals (e.g., commands or data). The processor 110 may communicate with the display module DM through an interface. For example, the processor 110 may use one of the communication methods described above but is not limited thereto.

The electronic device DD according to various examples disclosed herein may be implemented in various shapes. For example, the electronic device DD may include at least one of a portable communication device (e.g., a smartphone), a computing device, a portable multimedia device, a portable medical device, a camera, a wearable device, or a home appliance. However, the electronic device DD according to embodiments is not limited to the above-described devices.

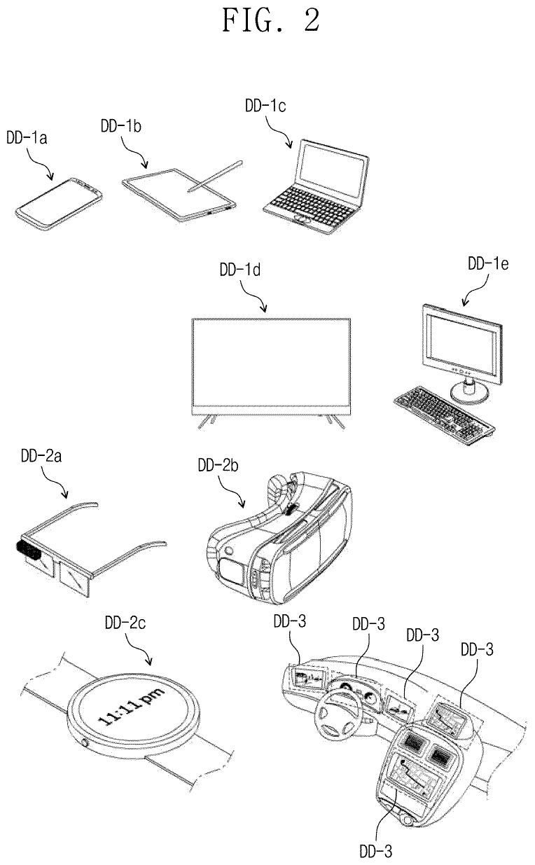

FIG. 2 is schematic views of various electronic devices according to embodiments of the inventive concepts.

Referring to FIG. 2, various electronic devices to which the display module DM according to embodiments of the inventive concepts is applied may include: image display electronic devices such as a smartphone DD-1a, a tablet personal computer (PC) DD-1b, a laptop DD-1c, a television (TV) DD-1d, or a desktop monitor DD-1e; wearable electronic devices such as smart glasses DD-2a, a head-mounted display DD-2b, or a smartwatch DD-2c; and vehicle electronic devices DD-3 such as an instrument panel (e.g., an automotive instrument panel), a center fascia (e.g., an automotive center fascia), a dashboard-mounted CID (center information display), or a room mirror display.

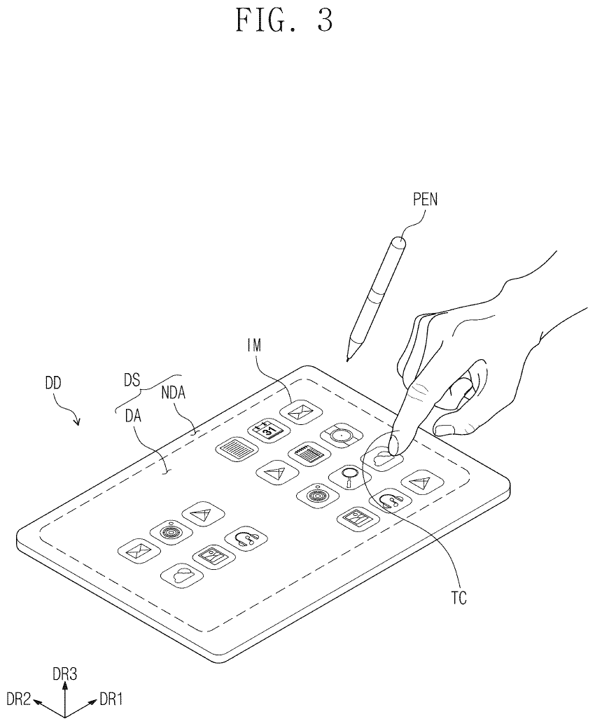

FIG. 3 is a perspective view of an electronic device according to embodiments of the inventive concepts.

The electronic device DD according to embodiments may be a device that is activated in response to an electrical signal. For example, the electronic device DD may be a television, an outdoor billboard (or signboard), a personal computer, a notebook computer, a personal digital terminal, a monitor, a mobile phone, a tablet, a navigation device (e.g., an in-vehicle navigation device), a game console, a camera, or a wearable device, but is not limited to these examples. In FIG. 3, a tablet is illustrated as an example of the electronic device DD.

Referring to FIG. 3, the electronic device DD according to embodiments of the inventive concepts may have long sides extending in parallel with a first direction DR1 and short sides extending in parallel with a second direction DR2 intersecting the first direction DR1. Corners of the electronic device DD connecting the long sides and short sides may have a curved shape. The corners having a curved shape may be defined as round corners, The overall shape of the electronic device DD may be defined as a round-cornered rectangle. However, this is merely an example of the shape of the electronic device DD and the shape of the electronic device is not limited to a round-cornered rectangle.

Hereinafter, a direction substantially perpendicular to a plane defined by the first direction DR1 and the second direction DR2 is defined as a third direction DR3. In the present specification, a “planar” reference refers to a view seen from the third direction DR3. The directions indicated by the first to third directional axes DR1, DR2, and DR3 are relative and may be converted to different directions. Hereinafter, the first to third directions are referred to by the same reference numerals as (or similar reference numerals to) the first to third directional axes DR1, DR2, and DR3, respectively.

A front surface of the electronic apparatus DD may be defined as a display surface DS and may have a plane defined by the first direction DR1 and the second direction DR2. Through the display surface DS, images IM generated in the electronic apparatus DD may be provided to a user.

The display surface DS may include a display area DA and a non-display area NDA surrounding the display area DA. The display area DA may display an image, and the non-display area NDA may not display an image. A non-display area NDA may surround a display area DA and may define an edge of an electronic apparatus DD that is printed in a color.

The display area DA may have a rounded rectangular shape depending on a shape of the electronic apparatus DD. For example, the display area DA may include sides of a rectangle extending in a first direction DR1 and a second direction DR2, and rounded corners connecting the sides. Among the four sides, the sides extending in the first direction DR1 may be defined as long sides, and the sides extending in the second direction DR2 among the four sides may be defined as short sides.

The electronic apparatus DD may detect inputs applied from outside the electronic apparatus DD. For example, the electronic apparatus DD may detect a first input by a touch pen PEN and a second input by a touch TC. The touch pen PEN may be defined as an input device.

The touch pen PEN may be an active pen that outputs a signal. The second input by the touch TC may include various types of external inputs such as a part of a user's body, light, heat, or pressure.

The electronic apparatus DD and the touch pen PEN may communicate with each other bidirectionally. The electronic apparatus DD may provide an uplink signal to the touch pen PEN. For example, the uplink signal may include information such as panel information and a protocol version, but is not particularly limited thereto.

The touch pen PEN may provide a downlink signal to the electronic apparatus DD. The downlink signal may include synchronization signals or state information of the touch pen PEN. For example, the downlink signal may include coordinate information of the touch pen PEN, battery information of the touch pen PEN, tilt information of the touch pen PEN, and/or various types of information stored in the touch pen PEN, but it is not particularly limited thereto.

The display area DA of the electronic apparatus DD may display an image IM. The image IM may include not only dynamic images but also still images. In FIG. 3, a plurality of icons are illustrated as an example of the image IM.

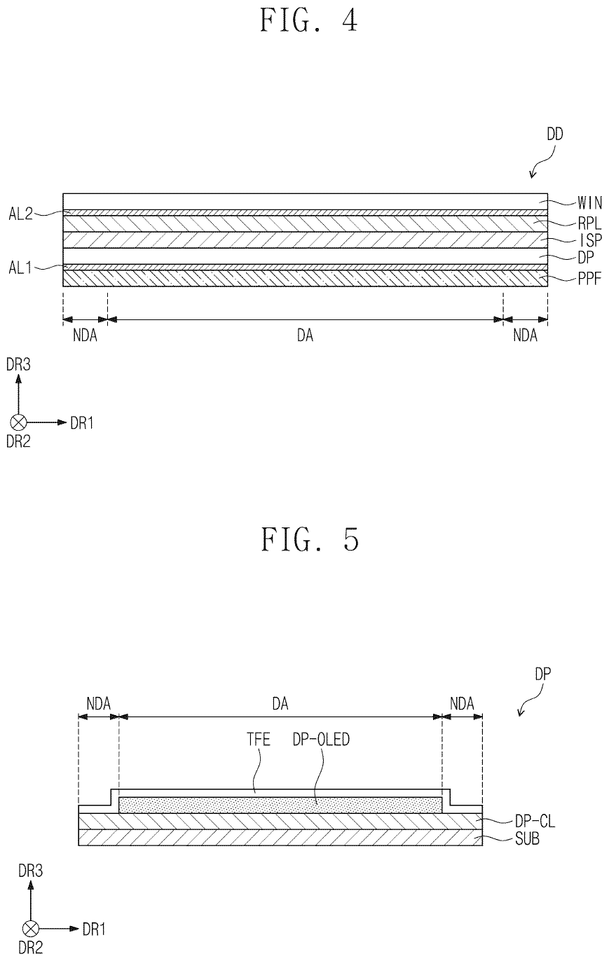

FIG. 4 is a cross-sectional view of the electronic device according to embodiments of the inventive concepts.

FIG. 4 is a cross-sectional view schematically illustrating the electronic apparatus shown in FIG. 3. In FIG. 4, a cross-section of the electronic apparatus DD viewed from the second direction DR2 is illustrated as an example. In FIG. 4, some of the components of the electronic apparatus DD described in FIG. 3 are omitted from illustration.

Referring to FIG. 4, the electronic apparatus DD may include a display panel DP, an input sensor ISP, an anti-reflection layer RPL, a window module WIN, a panel protection film PPF, and/or first and second adhesive layers AL1 and AL2. The input sensor ISP illustrated in FIG. 4 may be the same configuration as (or a similar configuration to) the input sensor 161-2 described in FIG. 1.

The display panel DP according to embodiments of the inventive concepts may be an emission type display panel. For example, the display panel DP may include an organic light emitting display panel or an inorganic light emitting display panel. An emission layer of an organic light-emitting display panel may include an organic light-emitting material. An emission layer of an inorganic light-emitting display panel may include quantum dots and quantum rods. Hereinafter, the display panel DP is described as an organic light-emitting display panel.

The input sensor ISP may be disposed on the display panel DP. An input sensor ISP may include a plurality of sensing parts (not shown) configured to sense external inputs by a capacitive method. The input sensor ISP may be directly manufactured on a display panel DP during manufacturing of an electronic apparatus DD. Accordingly, the input sensor ISP according to embodiments may be directly disposed on the display panel DP. However, the input sensor ISP is not limited thereto, and may be manufactured as a separate panel from the display panel DP and may be attached to the display panel DP by an adhesive layer.

An anti-reflection layer RPL may be disposed on the input sensor ISP. The anti-reflection layer RPL may be directly manufactured on the input sensor ISP during manufacturing of the electronic apparatus DD. However, the anti-reflection layer RPL is not limited thereto, and may be manufactured as a separate panel and may be attached to the input sensor ISP by an adhesive layer.

The anti-reflection layer RPL may be defined as an external light reflection prevention (or reduction) film. The anti-reflection layer RPL may reduce a reflectance of external light incident from above the electronic apparatus DD toward the display panel DP. Due to the anti-reflection layer RPL, the external light may not be visually recognized by a user.

In a case where the external light that has traveled toward the display panel DP is reflected from the display panel DP and then redirected to an external user, the user may recognize the external light as in a mirror. To prevent (or reduce) such a phenomenon, for example, the anti-reflection layer RPL may include a plurality of color filters configured to display the same color as (or a similar color to) pixels of the display panel DP.

The color filters may filter the external light into the same color as (or a similar color to) the pixels. In this case, the external light may not be recognized by the user. However, the anti-reflection layer RPL is not limited thereto, and may include a retarder and/or a polarizer to reduce the reflectance of the external light.

A window module WIN may be disposed on the anti-reflection layer RPL. The window module WIN may protect the display panel DP, the input sensor ISP, and the anti-reflection layer RPL from external scratches and impacts.

A panel protection film PPF may be disposed below the display panel DP. The panel protection film PPF may protect a lower portion of the display panel DP. The panel protection film PPF may include a flexible plastic material such as polyethylene terephthalate (PET).

A first adhesive layer AL1 may be disposed between the display panel DP and the panel protection film PPF, and the display panel DP and the panel protection film PPF may be bonded to each other by the first adhesive layer AL1. A second adhesive layer AL2 may be disposed between the window module WIN and the anti-reflection layer RPL, and the window module WIN and the anti-reflection layer RPL may be bonded to each other by the second adhesive layer AL2.

FIG. 5 is a cross-sectional view of a display panel according to embodiments of the inventive concepts.

FIG. 5 is a cross-sectional view schematically illustrating the display panel DP shown in FIG. 4. For example, in FIG. 5, a cross-section of the display panel DP viewed from the second direction DR2 is illustrated.

Referring to FIG. 5, the display panel DP may include a substrate SUB, a circuit element layer DP-CL disposed on the substrate SUB, a display element layer DP-OLED disposed on the circuit element layer DP-CL, and/or a thin film encapsulation layer TFE disposed on the display element layer DP-OLED.

The substrate SUB may include a display region DA and a non-display region NDA around the display region DA. The substrate SUB may include glass or may include a flexible plastic material such as polyimide. The display element layer DP-OLED may be disposed on a display area DA.

A plurality of pixels may be disposed on the circuit element layer DP-CL and the display element layer DP-OLED. Each of the pixels may include a transistor disposed in a circuit element layer DP-CL, and a light-emitting element OLED disposed in a display element layer DP-OLED and connected to the transistor.

The thin film encapsulation layer TFE may be disposed on the circuit element layer DP-CL to cover the display element layer DP-OLED. The thin film encapsulation layer TFE may protect the pixels from moisture, oxygen, and external foreign substances. The thin film encapsulation layer TFE may include inorganic layers and an organic layer. The organic layer may be disposed between the inorganic layers, may be sealed by the inorganic layers, and may provide a planar surface. According to embodiments, the organic layer may be disposed on the inorganic layers or may be omitted, and is not limited to any one example.

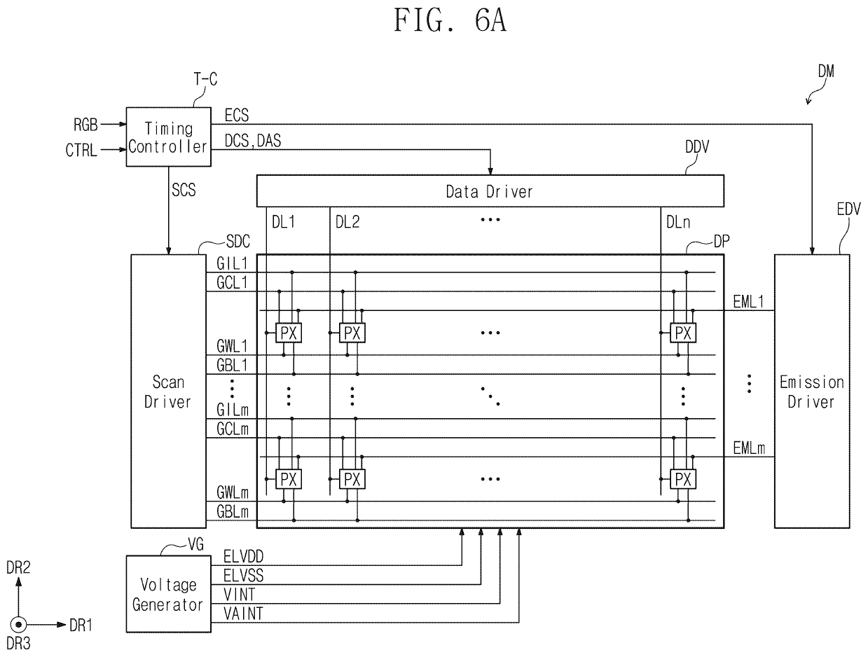

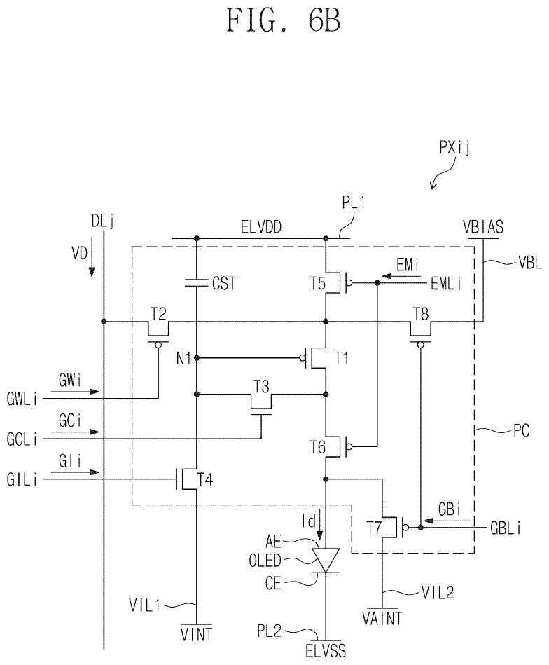

FIG. 6A is a block diagram of a display module according to embodiments of the inventive concepts.

Referring to FIG. 6A, the display module DM may include a display panel DP, a timing controller T-C, a scan driver SDC, a data driver DDV, a light emission driver EDV, and/or a voltage generator VG.

The display panel DP may include a plurality of scan lines GIL1 to GILm, GCL1 to GCLm, GWL1 to GWLm, and GBL1 to GBLm, a plurality of light emission lines EML1 to EMLm, a plurality of data lines DL1 to DLn, and/or a plurality of pixels PX. Here, m and n are natural numbers.

Pixels PX may be electrically connected to scan lines GIL1 to GILm, GCL1 to GCLm, GWL1 to GWLm, and GBL1 to GBLm, emission lines EML1 to EMLm, and data lines DL1 to DLn, respectively. Each of the pixels PX may be electrically connected to four corresponding scan lines, one corresponding data line, and one corresponding light emission line.

The scan lines GIL1 to GILm, GCL1 to GCLm, GWL1 to GWLm, and GBL1 to GBLm may include a plurality of initialization scan lines GIL1 to GILm, a plurality of compensation scan lines GCL1 to GCLm, a plurality of writing scan lines GWL1 to GWLm, and a plurality of bias scan lines GBL1 to GBLm.

Each of the pixels PX may be connected to one corresponding initialization scan line of the initialization scan lines GIL1 to GILm, one corresponding compensation scan line of the compensation scan lines GCL1 to GCLm, one corresponding writing scan line of the writing scan lines GWL1 to GWLm, and one corresponding bias scan line of the bias scan lines GBL1 to GBLm.

The scan lines GIL1 to GILm, GCL1 to GCLm, GWL1 to GWLm, and GBL1 to GBLm may be connected to a scan driver SDC, may extend in a first direction DR1, and may be arranged in (or along) a second direction DR2. The light emission lines EML1 to EMLm may be connected to the light emission driver EDV, may extend in the first direction DR1, and may be arranged in (or along) the second direction DR2. The data lines DL1 to DLn may be connected to the data driver DDV, may extend in the second direction DR2, and may be arranged in (or along) the first direction DR1.

The scan driver SDC, a light emission driver EDV, and/or a data driver DDV may be substantially disposed on a display panel DP.

The timing controller T-C may receive an image signal RGB and a control signal CTRL. The timing controller T-C may generate an image data signal DAS by converting a data format of the image signal RGB to match an interface specification with the data driver DDV. The timing controller T-C may output a scan control signal SCS, a data control signal DCS, and a light emission control signal ECS in response to the control signal CTRL.

The voltage generator VG may generate voltages required (or otherwise, used) for an operation of the display panel DP. The voltage generator VG may generate a first driving voltage ELVDD, a second driving voltage ELVSS, a first initialization voltage VINT, and a second initialization voltage VAINT. The first driving voltage ELVDD, the second driving voltage ELVSS, the first initialization voltage VINT, and the second initialization voltage VAINT may be applied to the pixels PX.

The scan driver SDC may receive a scan control signal SCS from a timing controller T-C. The scan driver SDC may output scan signals to the scan lines GIL1 to GILm, GCL1 to GCLm, GWL1 to GWLm, and GBL1 to GBLm in response to the scan control signal SCS. The scan signals may be applied to the pixels PX through the scan lines GIL1 to GILm, GCL1 to GCLm, GWL1 to GWLm, and GBL1 to GBLm.

The data driver DDV may receive a data control signal DCS and an image data signal DAS from the timing controller T-C. The data driver DDV may convert the image data signal DAS into data signals and output the data signals. The data signals may be defined as analog voltages corresponding to grayscale levels of the image data signal DAS. The data signals may be applied to the pixels PX through the data lines DL1 to DLn.

The light emission driver EDV may receive a light emission control signal ECS from the timing controller T-C. The light emission driver EDV may output light emission signals to the light emission lines EML1 to EMLm in response to the light emission control signal ECS. The light emission signals may be applied to the pixels PX through the light emission lines EML1 to EMLm.

The pixels PX may receive the data voltages in response to the scan signals. The pixels PX may emit light having brightness corresponding the data voltages in response to the emission signals to display an image.

FIG. 6B is an equivalent circuit diagram of a pixel according to embodiments of the inventive concepts.

FIG. 6B is a diagram illustrating an equivalent circuit of one of the pixels PX shown in FIG. 6A.

For example, in FIG. 6B, a pixel PXij connected to a j-th data line DLj, i-th scan lines GWLi, GCLi, GILi, and GBLi, and an i-th emission line EMLi is illustrated. Here, i and j are natural numbers.

Referring to FIG. 6B, the pixel PXij may include a pixel circuit PC and a light-emitting element OLED connected to the pixel circuit PC. The pixel circuit PC may drive the light-emitting element OLED.

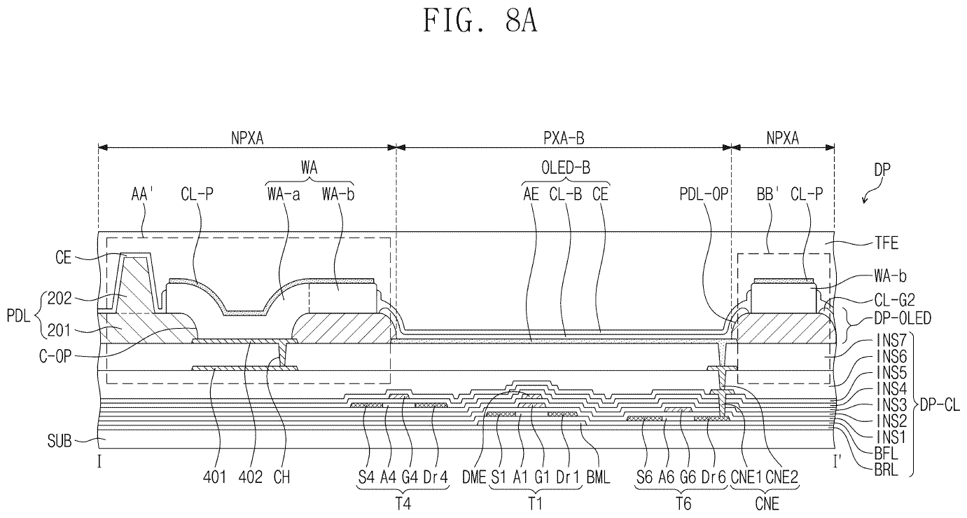

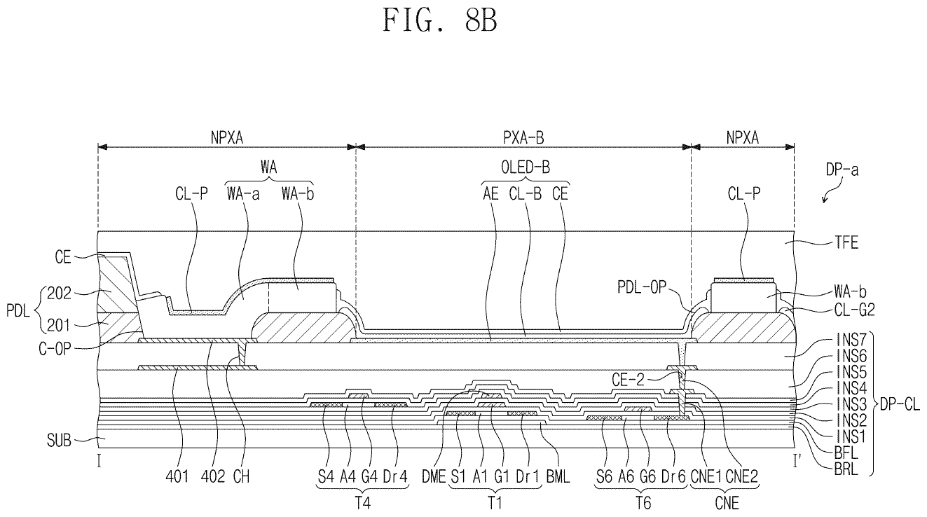

The pixel circuit PC may include a plurality of transistors T1 to T8, a first conductive pattern 401 (see FIG. 8A), and a capacitor CST. The transistors T1 to T8 and the capacitor CST may control an amount of current flowing through the light-emitting element OLED. The light-emitting element OLED may generate light having a luminance according to the supplied amount of current.

The i-th writing scan line GWLi may receive an i-th writing scan signal GWi, and the i-th compensation scan line GCLi may receive an i-th compensation scan signal GCi. The i-th initialization scan line GILi may receive an i-th initialization scan signal GIi, and the i-th bias scan line GBLi may receive an i-th bias scan signal Gbi. The i-th light emission line EMLi may receive an i-th light emission signal EMi.

The pixel PXij may be connected to a j-th data line DLj, the i-th writing scan line GWLi, the i-th compensation scan line GCLi, the i-th initialization scan line GILi, the i-th bias scan line GBLi, the i-th light emission line EMLi, a first initialization line VIL1, a second initialization line VIL2, a bias line VBL, and first and second power lines PL1 and PL2.

The first initialization line VIL1 may receive a first initialization voltage VINT, and the second initialization line VIL2 may receive a second initialization voltage VAINT. The bias line VBL may receive a bias voltage VBIAS. The first power line PL1 may receive a first driving voltage ELVDD, and the second power line PL2 may receive a second driving voltage ELVSS.

Each of the transistors T1 to T8 may include a source electrode, a drain electrode, and a gate electrode. Hereinafter, in FIG. 6B, for convenience, one of the source electrode and the drain electrode may be defined as a first electrode, and the other may be defined as a second electrode. In addition, the gate electrode is defined as a control electrode.

The transistors T1 to T8 may include first to eighth transistors T1 to T8. The first, second, and fifth to eighth transistors T1, T2, and T5 to T8 may be p-channel metal-oxide semiconductor (PMOS) transistors. The third and fourth transistors T3 and T4 may be n-channel metal-oxide semiconductor (NMOS) transistors.

The first transistor T1 may be defined as a driving transistor, and the second transistor T2 may be defined as a switching transistor. The third transistor T3 may be defined as a compensation transistor. The fourth transistor T4 and the seventh transistor T7 may be defined as initialization transistors. The fifth transistor T5 and the sixth transistor T6 may be defined as light emission control transistors. The eighth transistor T8 may be defined as a bias transistor.

The light emitting element OLED may be defined as an organic light emitting element. The light-emitting element OLED may include a first electrode AE and a second electrode CE. The first electrode AE may receive a first driving voltage ELVDD through a sixth transistor T6, a first transistor T1, and a fifth transistor T5. The first driving voltage ELVDD may be applied to the pixel circuit PC through the first power line PL1.

The second electrode CE may receive a second driving voltage ELVSS having a level lower than the first driving voltage ELVDD. The second driving voltage ELVSS may be applied to the pixel circuit PC through the second power line PL2.

The first transistor T1 may be disposed between the fifth transistor T5 and the sixth transistor T6, and may be connected to the fifth transistor T5 and the sixth transistor T6. The first transistor T1 may be connected to a first power line PL1 through the fifth transistor T5 and may be connected to the first electrode AE through the sixth transistor T6.

The first transistor T1 may include a first electrode connected to the first power line PL1 through the fifth transistor T5, a second electrode connected to the first electrode AE through the sixth transistor T6, and a control electrode connected to a first node N1.

The first electrode of the first transistor T1 may be connected to the fifth transistor T5, and the second electrode of the first transistor T1 may be connected to the sixth transistor T6. The first transistor T1 may control an amount of current flowing through the light-emitting element OLED according to a voltage of the first node N1 applied to the control electrode of the first transistor T1.

The second transistor T2 may be disposed between the first transistor T1 and the j-th data line DLj, and may be connected to the first transistor T1 and the j-th data line DLj. The second transistor T2 may include a first electrode connected to the j-th data line DLj, a second electrode connected to the first electrode of the first transistor T1, and a control electrode connected to the i-th writing scan line GWLi.

The second transistor T2 may be turned on by an i-th writing scan signal GWi applied through the i-th writing scan line GWLi to electrically connect the j-th data line DLj and the first electrode of the first transistor T1. The second transistor T2 may perform a switching operation of supplying a data voltage VD (corresponding to the above-described data signal) received through the j-th data line DLj to the first electrode of the first transistor T1.

The third transistor T3 may be connected to the second electrode of the first transistor T1 and the first node N1. The third transistor T3 may include a first electrode connected to the second electrode of the first transistor T1, a second electrode connected to the first node N1, and a control electrode connected to the i-th compensation scan line GCLi.

The third transistor T3 may be turned on by an i-th compensation scan signal GCi applied through the i-th compensation scan line GCLi to electrically connect the second electrode and the control electrode of the first transistor T1. When the third transistor T3 is turned on, the first transistor T1 and the third transistor T3 may be connected in a diode configuration.

The fourth transistor T4 may be connected to the first node N1. The fourth transistor T4 may include a first electrode connected to the first node N1, a second electrode connected to the first initialization line VIL1, and a control electrode connected to the i-th initialization scan line GILi. The fourth transistor T4 may be turned on by an i-th initialization scan signal GIi applied through the i-th initialization scan line GILi to provide a first initialization voltage VINT received through the first initialization line VIL1 to the first node N1.

The fifth transistor T5 may include a first electrode connected to the first power line PL1, a second electrode connected to the first electrode of the first transistor T1, and a control electrode connected to an i-th emission line EMLi.

The sixth transistor T6 may include a first electrode connected to the second electrode of the first transistor T1, a second electrode connected to the first electrode AE, and a control electrode connected to the i-th light emission line EMLi.

The fifth transistor T5 and the sixth transistor T6 may be turned on by an i-th light emission signal EMi applied through the i-th light emission line EMLi. The fifth transistor T5 and the sixth transistor T6 may provide the first driving voltage ELVDD to the light-emitting element OLED, whereby a driving current may flow through the light-emitting element OLED. Accordingly, the light-emitting element OLED may emit light.

The seventh transistor T7 may include a first electrode connected to the first electrode AE, a second electrode connected to the second initialization line VIL2, and a control electrode connected to the i-th bias scan line GBLi. The seventh transistor T7 may be turned on by an i-th bias scan signal GBi applied through the i-th bias scan line GBLi to provide a second initialization voltage VAINT received through the second initialization line VIL2 to the first electrode AE of the light-emitting element OLED.

In embodiments of the inventive concepts, the second initialization voltage VAINT may have a level different from that of the first initialization voltage VINT, but is not limited thereto and may have the same level as (or a similar level to) the first initialization voltage VINT.

The seventh transistor T7 may improve black expression ability of the pixel PXij. When the seventh transistor T7 is turned on, a parasitic capacitor (not shown) of the light-emitting element OLED may be discharged. Accordingly, when implementing black luminance, the light-emitting element OLED may not emit light due to the leakage current of the first transistor T1, and thus black representation performance may be improved.

A capacitor CST may include a first electrode connected to the first power line PL1 and a second electrode connected to the first node N1. When the fifth transistor T5 and the sixth transistor T6 are turned on, an amount of current flowing through the first transistor T1 may be determined based on a voltage stored in the capacitor CST.

An eighth transistor T8 may include a first electrode connected to a bias line VBL, a second electrode connected to the first electrode of the first transistor T1, and a control electrode connected to an i-th bias scan line GBLi.

The eighth transistor T8 may be turned on by an i-th bias scan signal GBi and may supply a bias voltage VBIAS applied through the bias line VBL to the first electrode of the first transistor T1. However, transistors included in the pixel PXij are not limited thereto.

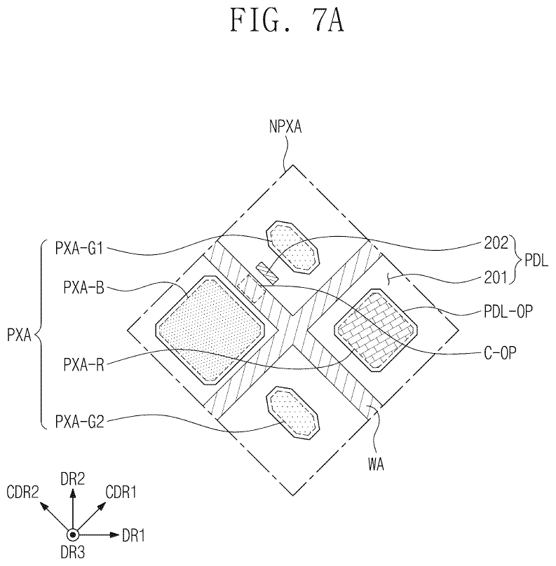

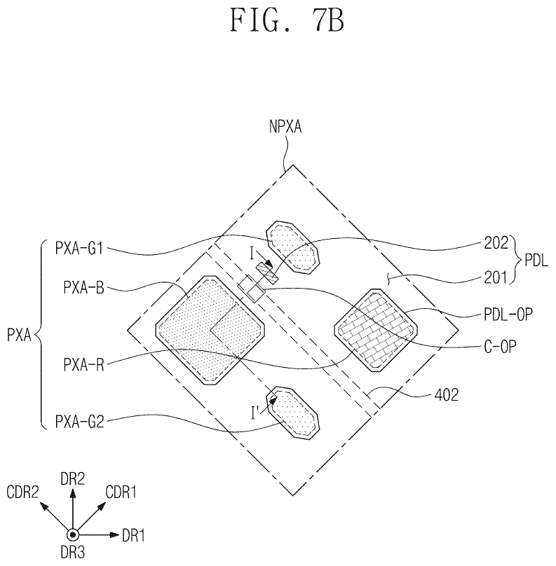

FIGS. 7A and 7B are plan views of a pixel defining layer according to embodiments of the inventive concepts.

FIGS. 7A and 7B are plan views schematically illustrating a partial region of a pixel defining layer PDL. The illustrated partial region may correspond to one pixel unit. The pixel unit may include the pixels described in FIGS. 6A and 6B. A plurality of pixel units may be provided and may be arranged along first and second diagonal directions CDR1 and CDR2 within a display area DA described in FIG. 3. In FIGS. 7A and 7B, the same reference numerals (or similar reference numerals) are used for the same components (or similar components), and repeated descriptions will be omitted.

In FIG. 7A, top surface boundaries of a pixel define layer PDL and a partition wall WA disposed in a partial region in a planar view are illustrated with solid lines. The boundary of the partial area illustrated in FIG. 7A is indicated by a single-dot chain line. A first partition wall WA-a disposed in a contact opening C-OP and a second partition wall WA-b corresponding to the remaining portion of the partition wall WA may have an integrated shape, as illustrated in FIG. 7A (see also FIG. 8A). This will be described later in detail. The pixel defining layer PDL may include a base layer 201 and a protrusion 202 overlapping the base layer 201. A plurality of emission openings PDL-OP and at least one contact opening C-OP may be defined in the base layer 201. A detailed description of the pixel defining layer PDL will be provided below. For convenience of explanation, the contact opening C-OP defined below the partition wall WA is illustrated with a dotted line.

Each of the emission openings PDL-OP may define a plurality of emission areas PXA-G1, PXA-G2, PXA-R, and PXA-B. Each of the plurality of emission areas PXA-G1, PXA-G2, PXA-R, and PXA-B is illustrated with a dotted line. Each of the emission areas PXA-G1, PXA-G2, PXA-R, and PXA-B may be an area on which a light-emitting element OLED is disposed, and may be an area where light generated by the light-emitting element OLED is displayed. The number of emission areas PXA is not limited, and in FIGS. 7A and 7B, four emission areas PXA-G1, PXA-G2, PXA-R, and PXA-B are illustrated as an example.

Specifically, a (1-1)-th emission area PXA-G1 may display first light. The first light may be, for example, green light, but is not limited thereto.

A (1-2)-th emission area PXA-G2 may be spaced apart from the (1-1)-th emission area PXA-G1 in a second direction DR2. The (1-2)-th emission area PXA-G2 may display light of the same color as (or a similar color to) that of the (1-1)-th emission area PXA-G1, and may be, for example, green light, but is not limited thereto.

A second emission area PXA-B, which displays second light, may be spaced apart from the (1-1)-th emission area PXA-G1 in a first diagonal direction CDR1, and may be spaced apart from the (1-2)-th emission area PXA-G2 in a second diagonal direction CDR2. The second emission area PXA-B may have a surface area greater than that of the (1-1)-th and (1-2)-th emission areas PXA-G1 and PXA-G2, but it is not limited thereto. The second light may have a color different from the first light, and may be, for example, blue light, but is not limited thereto.

A third emission area PXA-R, which displays third light, may be spaced apart from the (1-1)-th emission area PXA-G1 in the second diagonal direction CDR2, and may be spaced apart from the (1-2)-th emission area PXA-G2 in the first diagonal direction CDR1. The third emission area PXA-R may have a surface area greater than that of the (1-1)-th and (1-2)-th emission areas PXA-G1 and PXA-G2, and smaller than that of the second emission area PXA-B, but is not limited thereto. The third light may have a color different from the first light and the second light, and may be, for example, red light, but is not limited thereto.

A non-emission area NPXA may be defined by a pixel defining layer PDL. Accordingly, each of the emission areas PXA-G1, PXA-G2, PXA-R, and PXA-B may be surrounded in a planar view by the non-emission area NPXA.

The contact opening C-OP may be spaced apart from the emission areas PXA-G1, PXA-G2, PXA-R, and PXA-B in a planar view. The contact opening C-OP may be defined between the emission areas PXA-G1, PXA-G2, PXA-R, and PXA-B. Specifically, the contact opening C-OP may be defined between the second emission area PXA-B and the (1-1)-th emission area PXA-G1. The contact opening C-OP may be spaced apart from the (1-1)-th emission area PXA-G1 in the first diagonal direction CDR1. The contact opening C-OP may be spaced apart from the second emission area PXA-B in the first diagonal direction CDR1. In this example, although a single contact opening C-OP is illustrated, the number of contact openings C-OP defined within one pixel unit may be two or more and is not limited to any one example.

The contact opening C-OP may be defined adjacent to the protrusion 202. For example, the contact opening C-OP may be defined between one of the emission areas PXA and the protrusion 202, or may be defined in connection with one side of the protrusion 202. A detailed description of the contact opening will be provided below.

The contact opening C-OP may overlap at least a portion of a second conductive pattern 402 in a planar view, and the overlapping portion of the second conductive pattern 402 may be exposed by the contact opening C-OP. In this example, for ease of explanation, the second conductive pattern 402 is illustrated with dotted lines in FIG. 7B.

FIG. 7B omits the partition wall WA that is illustrated in FIG. 7A. Unlike FIG. 7A, FIG. 7B illustrates the boundary of the second conductive pattern 402 with a dotted line in the planar view. Additionally, unlike FIG. 7A, FIG. 7B illustrates the contact opening C-OP with a solid line.

The second conductive pattern 402 may receive a second driving voltage ELVSS (see FIG. 6B). Specifically, the second conductive pattern 402 may be connected to a first conductive pattern 401 (see FIG. 8A), and the first conductive pattern 401 (see FIG. 8A) may receive the second driving voltage ELVSS (see FIG. 6B). The first conductive pattern 401 (see FIG. 8A) may be a part of a second power line PL2 (see FIG. 6B) for supplying the second driving voltage ELVSS, or may be a separate conductive line connected to the second power line PL2. Although the second conductive pattern 402 is illustrated in a line shape, this is merely an example. The second conductive pattern 402 may have various shapes as long as it may receive the second driving voltage ELVSS (see FIG. 6B), and is not limited to any one example.

Referring to FIGS. 7A and 7B, the contact opening C-OP may have a rectangular shape in a planar view. In FIGS. 7A and 7B, one contact opening C-OP defined adjacent to the protrusion 202 is illustrated.

The position, number, and shape of the contact opening C-OP illustrated in FIGS. 7A and 7B are merely examples and embodiments are not limited thereto. The position and shape of the contact opening C-OP are not limited when the contact opening C-OP overlap at least a portion of the second conductive pattern 402 and allow the second conductive pattern 402 to be exposed. Here, a plurality of spaced contact openings C-OP may also be provided. The position and shape of the contact opening C-OP may vary depending on the position and shape of the emission areas PXA-G1, PXA-G2, PXA-R, and PXA-B.

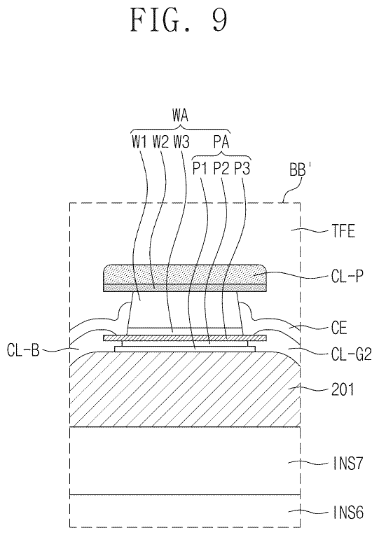

FIGS. 8A and 8B are cross-sectional views taken along line I-I′ of FIG. 7B. FIG. 9 is an enlarged view of the display panel DP according to embodiments of the inventive concepts.

FIGS. 8A and 8B are cross-sectional views taken along line I-I′ of FIG. 7B. FIG. 9 is an enlarged view of a region BB′ illustrated in FIG. 8A. For components identical (or similar) to those described in FIG. 8A, the same reference numerals (or similar reference numerals) are used in FIG. 9, and repeated descriptions will be omitted.

FIGS. 8A and 8B schematically illustrate a light-emitting element OLED-B disposed in one emission area PXA-B and partial components of a pixel PX connected thereto, including a first transistor T1, a fourth transistor T4, and a sixth transistor T6, as an example. Hereinafter, the inventive concepts will be described with reference to FIGS. 8A and 8B.

Referring to FIGS. 8A and 8B, a display panel DP may include a base substrate SUB, a circuit element layer DP-CL, a display element layer DP-OLED, and/or a thin film encapsulation layer TFE.

The base substrate SUB may include glass or may include a flexible plastic material such as polyimide. The circuit element layer DP-CL and the display element layer DP-OLED may be disposed on the base substrate SUB. The display element layer DP-OLED may include a light-emitting element OLED-B and a pixel defining layer PDL.

The circuit element layer DP-CL may be disposed on the base substrate SUB. The circuit element layer DP-CL may include a barrier layer BRL, a buffer layer BFL, a metal layer BML, a first conductive pattern 401, the first, fourth, and sixth transistors T1, T4, and T6, and a plurality of insulating layers INS1 to INS7. The plurality of transistors T1, T4, and T6 may include a plurality of semiconductor layers. A detailed description of the semiconductor layers will be provided below.

The barrier layer BRL may be disposed on the base substrate SUB. The barrier layer BRL may enhance bonding strength between a semiconductor pattern included in the transistors and the substrate SUB. The barrier layer BRL may include an inorganic material. A metal layer BML may be disposed on the barrier layer BRL. The metal layer BML may overlap the first transistor T1. According to embodiments, the metal layer BML may be supplied with a constant voltage. When a constant voltage is applied to the metal layer BML, a threshold voltage Vth of the first transistor T1 disposed on the metal layer BML may be maintained without change. The barrier layer BRL may include an inorganic material. For example, the barrier layer BRL may include one of silicon oxide and silicon nitride.

The metal layer BML may be disposed on the barrier layer BRL. The metal layer BML may overlap, in a planar view, the first transistor T1, particularly a semiconductor layer S1, A1, Dr1 of the first transistor T1. The metal layer BML may block light incident from below the metal layer BML into the first transistor T1. The metal layer BML may include a reflective metal. According to embodiments, the metal layer BML may be omitted.

A buffer layer BFL may be disposed on the barrier layer BRL and may cover the metal layer BML. The buffer layer BFL may include an inorganic material. For example, the barrier layer BRL may include one of silicon oxide and silicon nitride.

The first transistor T1 and the sixth transistor T6 may be disposed on the buffer layer BFL. Specifically, the first transistor T1 may include a semiconductor layer S1, A1, and Dr1, and the sixth transistor T6 may include a semiconductor layer S6, A6, and Dr6.

The semiconductor layers S1, A1, and Dr1 of the first transistor T1 and the semiconductor layers S6, A6, and Dr6 of the sixth transistor T6 may be disposed on the buffer layer BFL. The semiconductor layers S1, A1, Dr1, S6, A6, and Dr6 may include polysilicon. However, the semiconductor layers S1, A1, Dr1, S6, A6, and Dr6 may include amorphous silicon and are not limited thereto.

The semiconductor layers S1, A1, Dr1, S6, A6, and Dr6 may be doped with an N-type dopant or a P-type dopant. The semiconductor layers S1, A1, Dr1, S6, A6, and Dr6 may include a high-doping region and a low-doping region. The high-doping region may have higher conductivity than that in the low-doping region and may substantially serve as source and drain electrodes of the first and sixth transistors T1 and T6. The low-doping region may substantially correspond to an active (or channel) region of the first and sixth transistors T1 and T6.

A first source region S1, a first channel region A1, and a first drain region Dr1 of the first transistor T1 may be provided from the first semiconductor layer S1, A1, and Dr1. The first channel region A1 may be disposed between the first source region S1 and the first drain region Dr1. The first transistor may correspond to the first transistor T1 of FIG. 6B described above.

A sixth source region S6, a sixth channel region A6, and a sixth drain region Dr6 of the sixth transistor T6 may be provided from the sixth semiconductor layer S6, A6, and Dr6. The sixth channel region A6 may be disposed between the sixth source region S6 and the sixth drain region Dr6. The sixth transistor T6 may correspond to the sixth transistor T6 illustrated in FIG. 6B.

A first insulating layer INS1 may be disposed on the buffer layer BFL to cover the semiconductor layers S1, A1, Dr1, S6, A6, and Dr6. A first gate electrode G1 (or control electrode) of the first transistor T1 and a sixth gate electrode G6 (or control electrode) of the sixth transistor T6 may be disposed on the first insulating layer INS1. In a top view, the first gate electrode G1 may overlap the first channel region A1, and the sixth gate electrode G6 may overlap the sixth channel region A6.

A second insulating layer INS2 may be disposed on the first insulating layer INS1 to cover the first and sixth gate electrodes G1 and G6. A dummy electrode DME may be disposed on the second insulating layer INS2. The dummy electrode DME may be disposed above the first gate electrode G1 and, in a top view, may overlap the first gate electrode G1. The dummy electrode DME may provide the above-described capacitor together with the first gate electrode G1.

A third insulating layer INS3 may be disposed on the second insulating layer INS2 to cover the dummy electrode DME. A fourth transistor T4 may include a semiconductor layer S4, A4, and Dr4, and the semiconductor layer S4, A4, and Dr4 of the fourth transistor T4 may be disposed on a third insulating layer INS3. Each of the semiconductor layers S4, A4, and Dr4 may include an oxide semiconductor composed of a metal oxide. Oxide semiconductors may include crystalline or amorphous oxide semiconductors.

The semiconductor layers S4, A4, and Dr4 may include a plurality of regions distinguished according to whether the metal oxide is reduced. A region in which the metal oxide is reduced (hereinafter, reduced region) may have higher conductivity than a region in which the metal oxide is not reduced (hereinafter, non-reduced region). The reduced region may substantially serve as a source electrode or a drain electrode of the fourth transistor T4. The non-reduced region may substantially correspond to an active region (or channel) of the fourth transistor T4.

A fourth source region S4, a fourth channel region A4, and a fourth drain region Dr4 of the fourth transistor T4 may be provided from the semiconductor layers S4, A4, and Dr4. The fourth channel region A4 may be disposed between the fourth source region S4 and the fourth drain region Dr4.

A fourth insulating layer INS4 may be disposed on the third insulating layer INS3 to cover the semiconductor layer S4, A4, Dr4. A fourth gate electrode G4 of the fourth transistor T4 may be disposed on the fourth insulating layer INS4. In a top view, the fourth gate electrode G4 may overlap the fourth channel region A4. A fifth insulating layer INS5 may be disposed on the fourth insulating layer INS4 to cover the fourth gate electrode G4.

Although not illustrated, each of the second, fifth, and seventh transistors T2, T5, and T7 may have a structure of a source region, a channel region, a drain region, and a gate electrode that is substantially the same as that of the first and sixth transistors T1 and T6. Although not shown, the source region, channel region, drain region, and gate electrode structure of the third transistor T3 may be substantially the same as that of the fourth transistor T4.

First to fifth insulating layers INS1 to INS5 may include an inorganic material. For example, the insulating layers INS1 to INS5 may include one of silicon oxide and silicon nitride, or one insulating layer may include multiple layered inorganic layers, and is not limited to any one example. The multiple inorganic layers may have a layered structure in which layers including silicon nitride and silicon oxide are alternately laminated.

A connection electrode CNE may be disposed between the sixth transistor T6 and a light-emitting element OLED-B. The connection electrode CNE may electrically connect the sixth transistor T6 and the light-emitting element OLED-B to each other. The connection electrode CNE may include a first connection electrode CNE1 and a second connection electrode CNE2 disposed on the first connection electrode CNE1.

The first connection electrode CNE1 may be disposed on the fifth insulating layer INS5, and may be connected to the sixth drain region Dr6 through a contact hole defined in the insulating layers INS1 to INS5. A sixth insulating layer INS6 may be disposed on the fifth insulating layer INS5 to cover the first connection electrode CNE1. The second connection electrode CNE2 may be disposed on the sixth insulating layer INS6. The second connection electrode CNE2 may be connected to the first connection electrode CNE1 through a contact hole defined in the sixth insulating layer INS6.

The first conductive pattern 401 may be disposed on the sixth insulating layer INS6. The first conductive pattern 401 may receive a second driving voltage ELVSS (see FIG. 6B). For example, the first conductive pattern 401 may be a part of the second power line PL2 (see FIG. 6B). Alternatively, the first conductive pattern 401 may be a separate pattern connected to the second power line PL2 (see FIG. 6B). According to embodiments, the second power line PL2 may be described herein as being included in the circuit element layer DP-CL at a position contacting (e.g., directly electrically connecting to) the first conductive pattern 401 (e.g., in a same layer as or a similar layer to the first conductive pattern 401), but embodiments are not limited thereto.

A seventh insulating layer INS7 may be disposed on the sixth insulating layer INS6. The seventh insulating layer may cover the first conductive pattern 401 and the second connection electrode CNE2. The sixth and seventh insulating layers INS6 and INS7 may include an organic material.

The display element layer DP-OLED may be disposed on the seventh insulating layer INS7. The display element layer DP-OLED may include the light-emitting element OLED-B, the second conductive pattern 402, the pixel defining layer PDL, and the partition wall WA.

The light-emitting element OLED-B may include the first electrode AE, the second electrode CE, and an intermediate layer CL-B.

The first electrode AE may be disposed on the seventh insulating layer INS7. The first electrode AE may be an anode. The first electrode AE may be a reflective electrode or a semi-transmissive electrode. For example, the first electrode AE may include indium tin oxide or indium zinc oxide. The first electrode AE may be provided in plurality and may be disposed in respective emission openings PDL-OP. The first electrode AE may be connected to the connection electrode CNE (e.g., to the second connection electrode CNE2) through a contact hole penetrating the seventh insulating layer INS7.

The second conductive pattern 402 may be disposed on the seventh insulating layer INS7. The second conductive pattern 402 may be connected to the first conductive pattern 401 through a contact hole CH penetrating the seventh insulating layer INS7. The second conductive pattern 402 may be disposed spaced apart from the first electrode AE on the seventh insulating layer INS7. That is, the second conductive pattern 402 may be at a same layer as (or a similar layer to) the first electrode AE. The second conductive pattern 402 may include the same material as (or a similar material to) the first electrode AE. Accordingly, the second conductive pattern 402 may be provided simultaneously (or contemporaneously) with the first electrode AE through the same process (or a similar process), and thus process cost may be reduced. However, the second conductive pattern 402 may include a material different from that of the first electrode AE and is not limited to any one example.

The pixel defining layer PDL may be disposed on the first electrode AE and the second conductive pattern 402. The pixel defining layer PDL may be an organic layer. The pixel defining layer PDL may include the emission opening PDL-OP and the contact opening C-OP. The emission opening PDL-OP and the contact opening C-OP may penetrate through a base layer 201 that will be described later. The emission opening PDL-OP and the contact opening C-OP may be defined spaced apart from each other. The emission opening PDL-OP may expose at least a portion of the first electrode AE, and the contact opening C-OP may expose at least a portion of the second conductive pattern 402.

The pixel defining layer PDL may include a base layer 201 and a protrusion 202 protruding upward from the base layer 201.

The protrusion 202 may be disposed on the base layer 201. A height of a part in which the protrusion 202 is provided may be greater than a thickness of the base layer 201. Accordingly, the protrusion 202 may serve as a spacer for maintaining a gap from a deposition mask during formation of the intermediate layer CL-B. Therefore, it may be possible to prevent (or reduce) damage to the display panel DP due to the deposition mask.

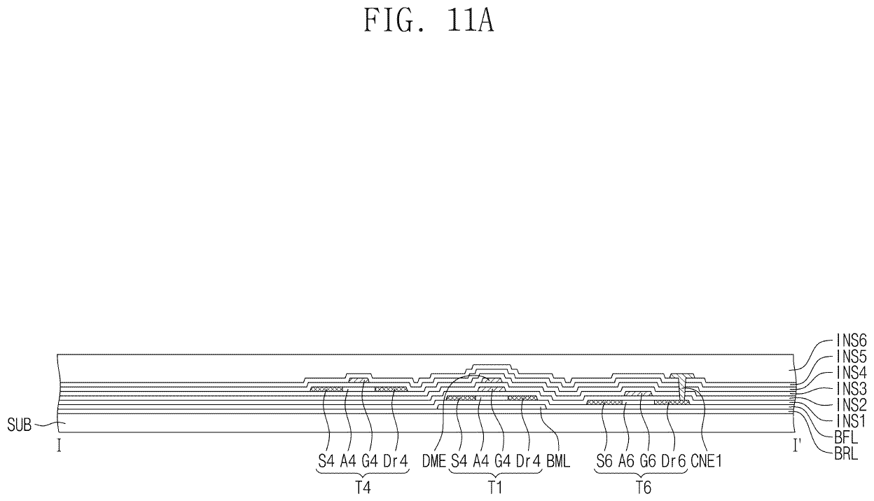

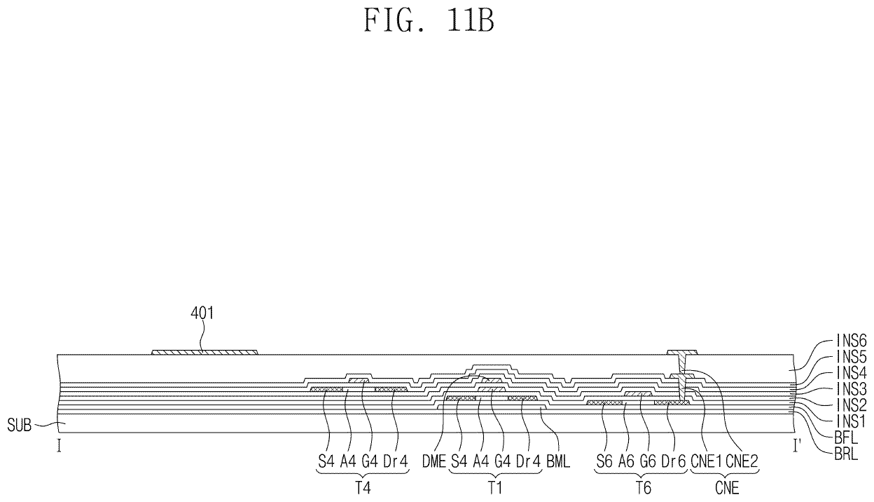

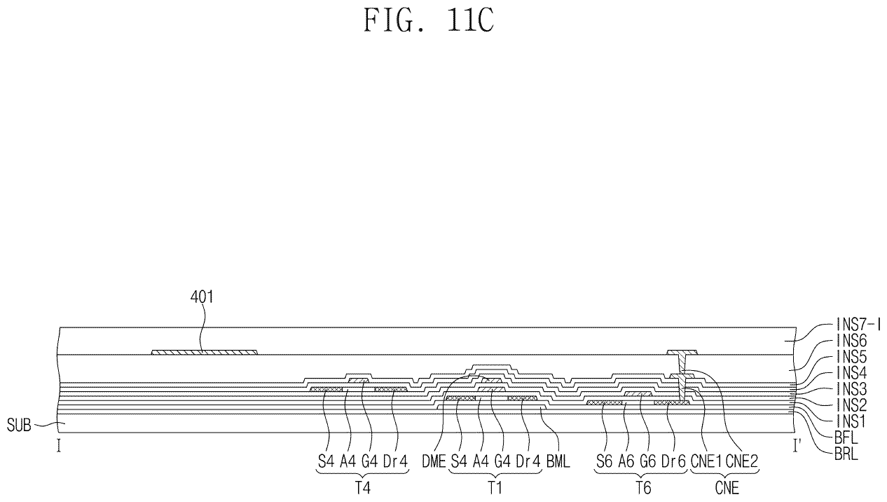

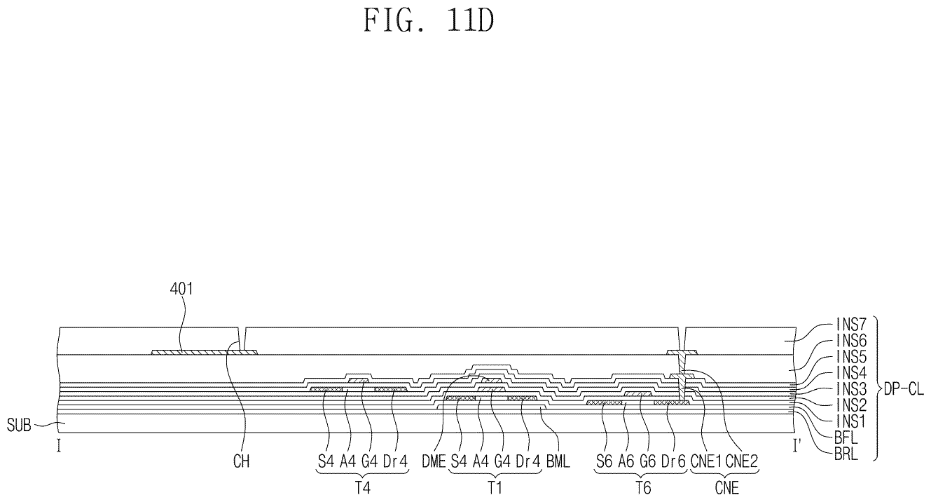

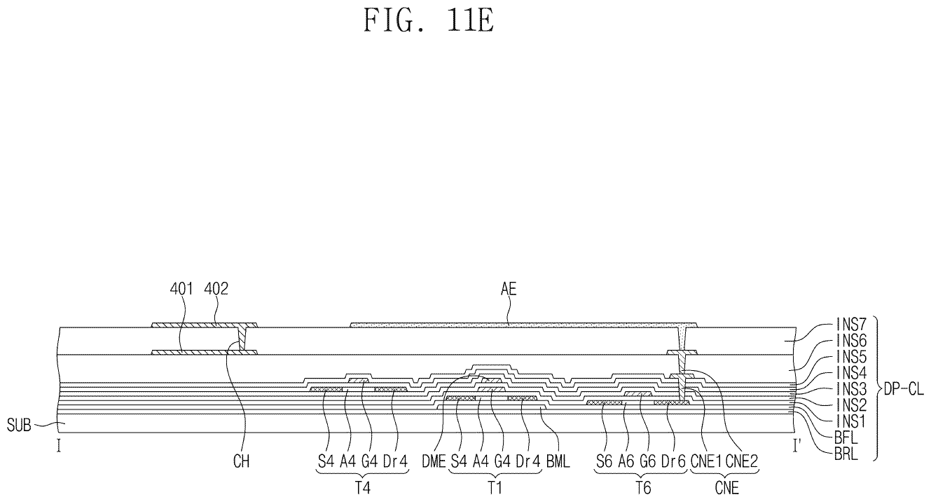

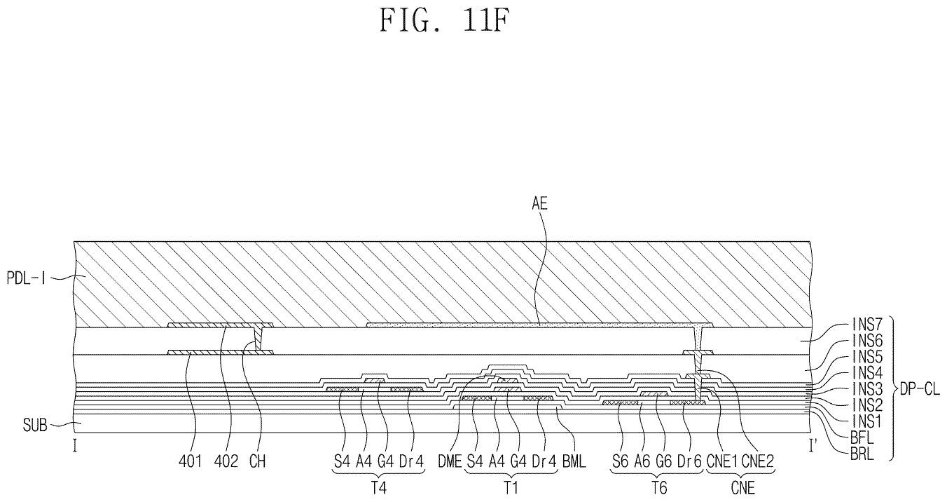

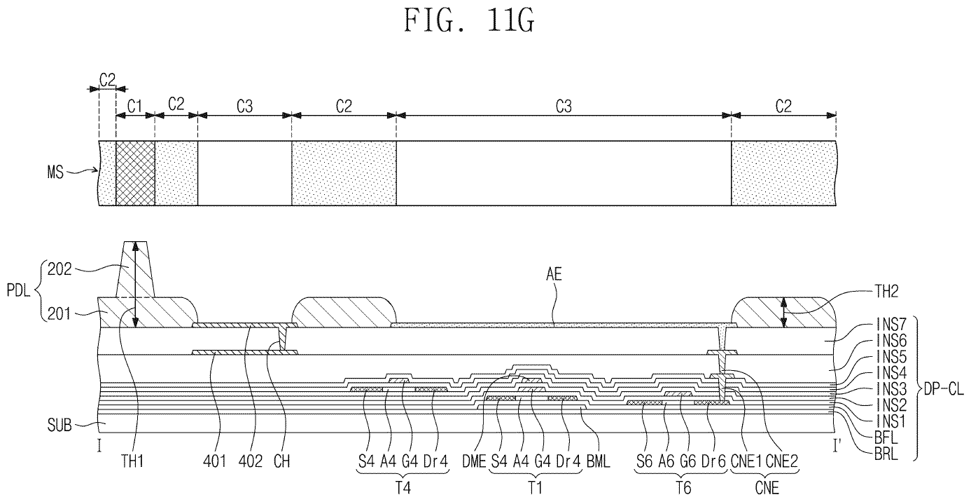

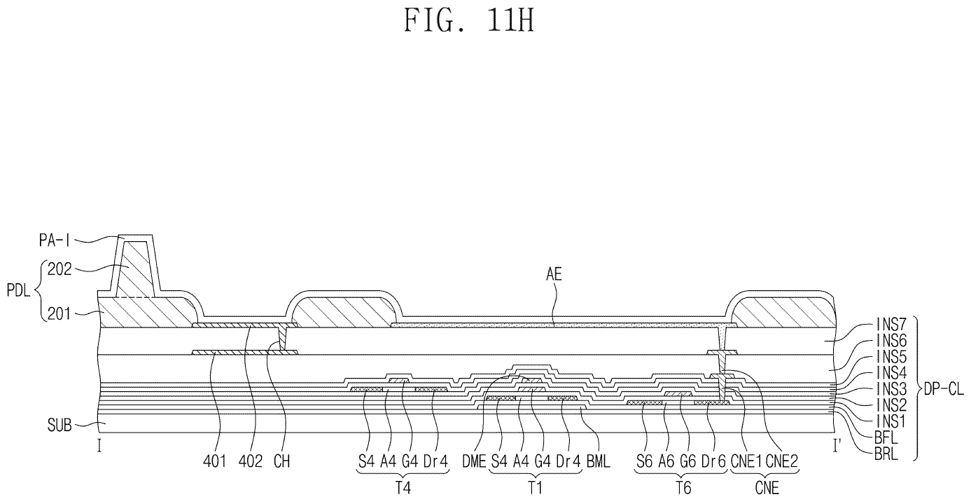

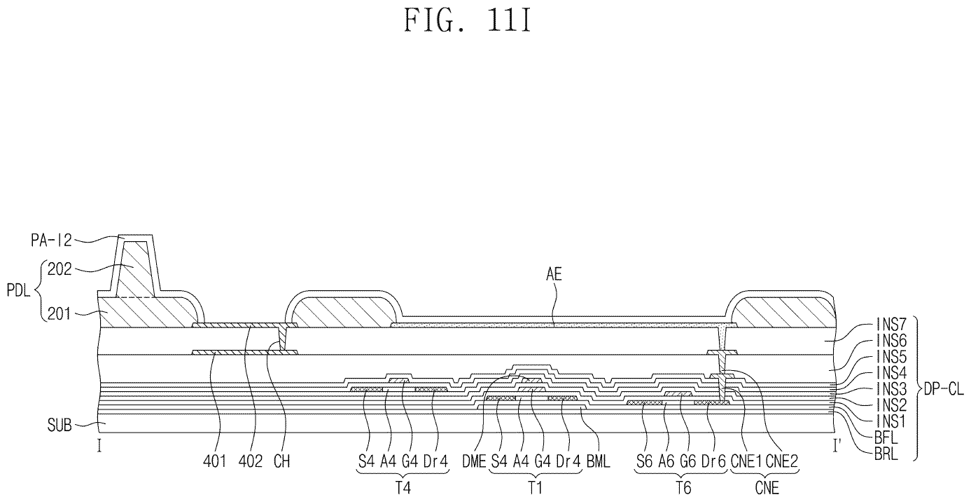

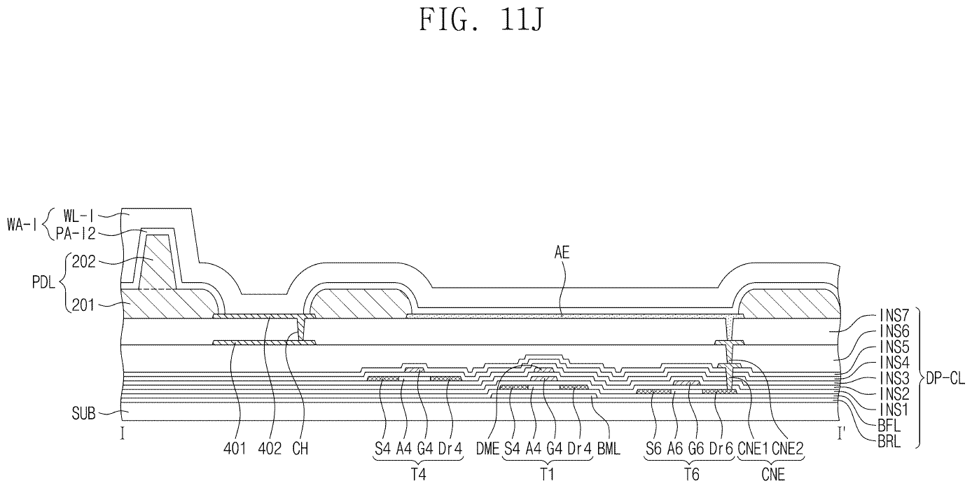

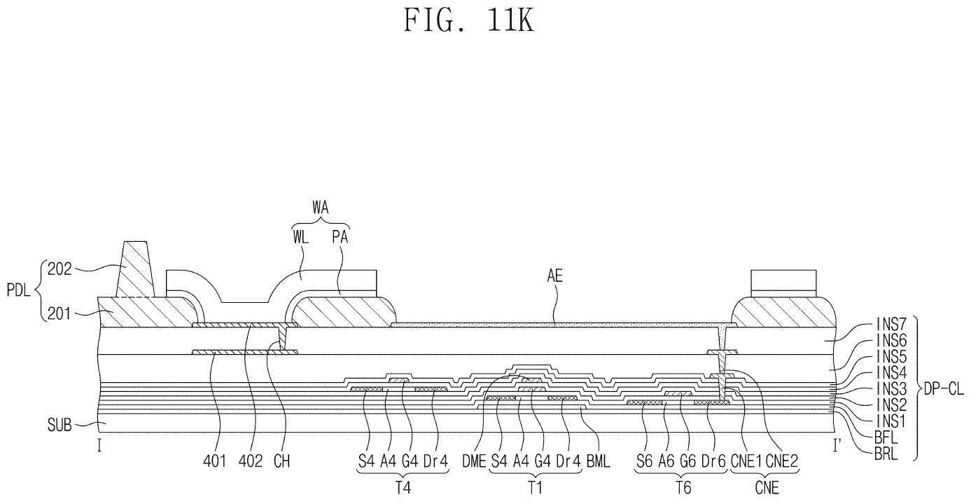

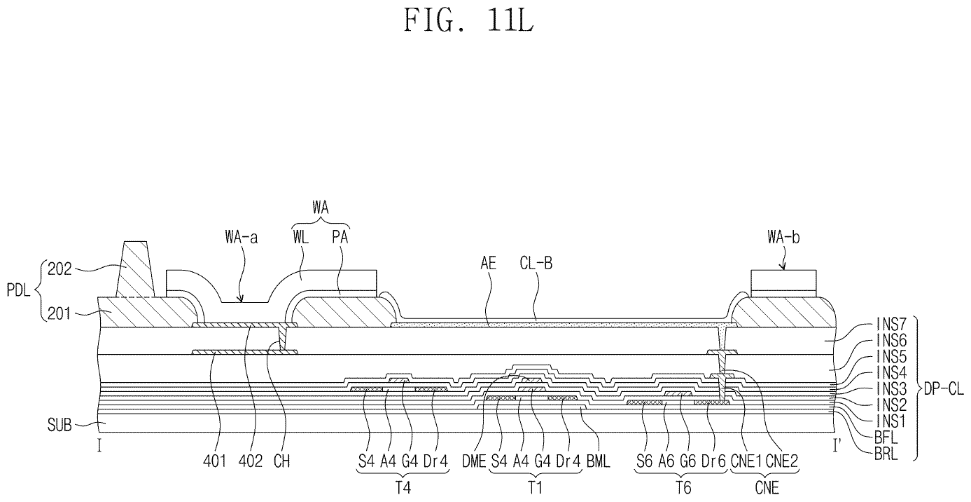

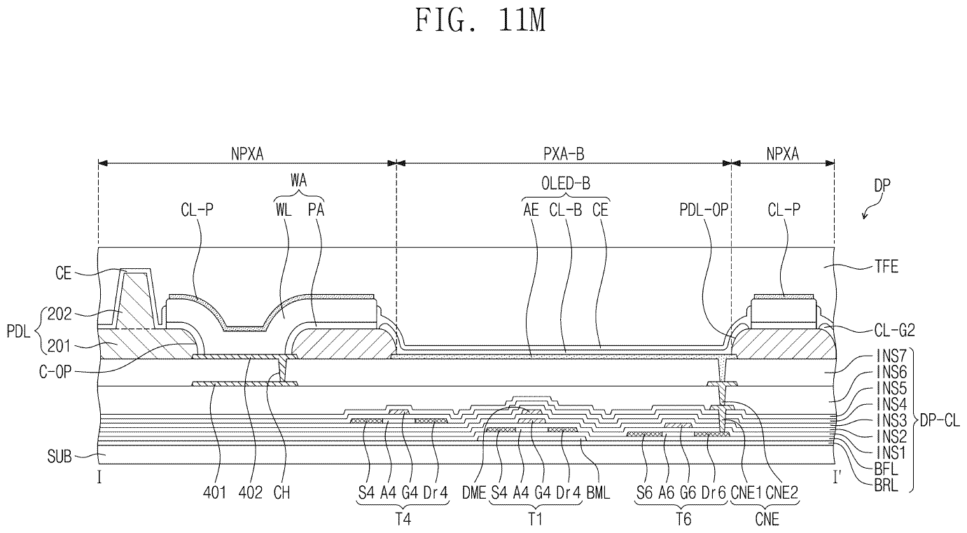

The protrusion 202 may be integrally provided with the base layer 201. That is, the protrusion 202 may include the same material as (or a similar material to) the base layer 201 and may be formed through a single mask MS (see FIG. 11G). Accordingly, the process for forming the protrusion 202 may be simplified, and the process cost may be reduced. A detailed description of the example will be provided below.

The intermediate layer CL-B may be disposed on a first electrode AE. Specifically, the intermediate layer CL-B may be disposed between the first electrode AE and the second electrode CE. The intermediate layer CL-B may be disposed in a emission opening PDL-OP. The intermediate layer CL-B may be provided by deposition. The intermediate layer CL-B may include a hole injection layer, a hole transport layer, a light-emitting layer, an electron transport layer, and/or an electron injection layer.

The second electrode CE may be disposed on the intermediate layer CL-B. The second electrode CE may be a transmissive electrode or a semi-transmissive electrode. For example, the second electrode CE may include indium zinc oxide. The second electrode CE may be a cathode or a common electrode. The second electrode CE may be commonly provided to a plurality of light-emitting devices OLEDs.

The second electrode CE may be connected to a second power line PL2 (see FIG. 6B) through a portion of the exposed second conductive pattern 402. Since a connection between the second electrode CE and the second power line PL2 (see FIG. 6B) may be easily achieved in the display area DA (see FIG. 3), challenges such as luminance defects caused by a voltage drop in the second electrode CE may be improved. A detailed description of the example will be provided below.

A display panel DP according to embodiments may include a partition wall WA. The partition wall WA may be disposed on a pixel defining layer PDL and may be disposed below the second electrode CE. The partition wall WA may disconnect the intermediate layer CL-B and allow the second electrode CE to be connected to the second power line PL2 (see FIG. 6B). The partition wall WA may include an electrically conductive material. The partition wall WA may be in contact with the second electrode CE. Accordingly, the second electrode CE may be connected to the second conductive pattern 402 and the second power line PL2 (see FIG. 6B) through the partition wall WA.

The partition wall WA may include a first partition WA-a and a second partition WA-b. The first partition WA-a may be defined as a portion of the partition wall WA disposed in a contact opening C-OP. The second partition WA-b may be defined as a portion of the partition wall WA disposed on the pixel defining layer PDL.

As illustrated in FIG. 8A, the first partition WA-a may be spaced apart from a protrusion 202 in a planar view. In this case, the first partition WA-a may be in contact with a base layer 201. Alternatively, as illustrated in FIG. 8B, the first partition WA-a of a display panel DP-a may be in contact with the protrusion 202. In this case, a side surface of the base layer 201 that defines the contact opening C-OP may be aligned with a side surface of the protrusion 202, and the first partition WA-a may extend along the side surface of the base layer 201 and the side surface of the protrusion 202. When the first partition WA-a may be connected to the second conductive pattern 402 through the contact opening C-OP, the shape or layout of the first partition WA-a may not be limited to one example.

The second partition WA-b may be disposed adjacent to the emission opening PDL-OP. When second partition WA-b may disconnect the intermediate layer CL-B, the shape or layout of the second partition WA-b may not be limited to one example.

According to embodiments of the inventive concepts, the first partition WA-a and the second partition WA-b may have an integral structure. For example, the first partition WA-a and the second partition WA-b may be connected and may have a mesh structure in which a plurality of openings are defined, as illustrated in FIG. 7A. The mesh structure may be disposed along the pixel defining layer PDL, and the openings may respectively overlap the emission openings PDL-OPs.

Referring to FIG. 9, the partition wall WA (e.g., the second partition WA-b of the region BB′) may include a first partition layer W1, a second partition layer W2, a third partition layer W3, and a protective layer PA.

The first partition layer W1 may be disposed on the pixel defining layer PDL. The first partition layer W1 may be electrically conductive. The first partition layer W1 may include aluminum Al. The intermediate layer CL-B may be disconnected, and the first partition layer W1 may be spaced apart from the intermediate layer CL-B. The first partition layer W1 may be in contact with the second electrode CE. The second partition layer W2 may be disposed on the first partition layer W1. The second partition layer W2 may be electrically conductive. The second partition layer W2 may include titanium Ti.

The partition wall WA may further include a third partition layer W3 disposed between the first partition layer W1 and the pixel defining layer PDL. The third partition layer W3 may be disposed between the first partition layer W1 and the pixel defining layer PDL. The third partition layer W3 may have a shape corresponding to a bottom surface of the first partition layer W1. The third partition layer W3 may be electrically conductive. The third partition layer W3 may be in contact with the second electrode CE. The third partition layer W3 may include molybdenum Mo. However, this is an example, and in the partition wall WA according to embodiments of the inventive concepts, the third partition layer W3 may be omitted.

The protective layer PA may be disposed below the third partition layer W3. The protective layer PA may be disposed between the pixel defining layer PDL and the third partition layer W3. The protective layer PA may be a sacrificial layer for preventing (or reducing) damage to the first electrode AE during etching process for forming the partition wall WA. The protective layer PA may cover the first electrode AE in the process of forming the partition wall WA, thereby protecting the first electrode AE. Subsequently, the first electrode AE may be exposed from the protective layer PA through a separate patterning process, and accordingly, the intermediate layer CL-B may be stably formed on the first electrode AE.

The protective layer PA may include a material having an etching selectivity different from those of the first partition layer W1 and the second partition layer W2. The protective layer PA according to embodiments may include a first protective layer P1, a second protective layer P2, and a third protective layer P3. According to embodiments, the first protective layer P1, the second protective layer P2, and the third protective layer P3 may be sequentially laminated. After depositing a material forming the first protective layer P1, depositing a material forming the second protective layer P2 thereon, and depositing a material forming the third protective layer P3 thereon, the stacked structure may be patterned through an etching process, thereby forming the first to third protective layers P1, P2, and P3 sequentially laminated. However, this is merely an example of forming the sequentially laminated first to third protective layers P1, P2, and P3, and the method of forming the sequentially laminated first to third protective layers P1, P2, and P3 is not limited thereto.

The first protective layer P1 may be disposed on the pixel defining layer PDL. The first protective layer P1 may include a metal oxide. For example, the first protective layer P1 may include at least one of indium zinc oxide, indium gallium zinc oxide, and/or indium tin oxide.

The second protective layer P2 may be disposed on the first protective layer P1. The second protective layer P2 may include a material different from that of the first protective layer P1. The second protective layer P2 may include an insulating material. For example, the second protective layer P2 may include at least one of silicon oxide, silicon oxynitride, and/or silicon nitride.

The third protective layer P3 may be disposed on the second protective layer P2. The third protective layer P3 may include a material different from those of the first protective layer P1 and the second protective layer P2. The third protective layer P3 may include an insulating material. For example, the third protective layer P3 may include at least one of silicon oxide, silicon oxynitride, and/or silicon nitride.

The first protective layer P1 may serve as a stopper when the second protective layer P2 and the third protective layer P3 are etched. However, this is merely an example. In the partition wall WA according to embodiments of the inventive concepts, the protective layer PA may be a single layer or may have a layered structure including a greater number of layers, or the protective layer PA may be omitted, and it is not limited to any particular example.

The partition wall WA may include at least one tip. When a surface of the partition wall WA adjacent (or nearest) to a base substrate SUB is defined as a bottom surface, a surface adjacent (or nearest) to a window module WIN (see FIG. 4) is defined as a top surface, and a surface connecting the top and bottom surfaces is defined as a side surface, the tip may be disposed on the side surface of the partition wall WA. Specifically, the tip may be a portion of the side surface of the partition wall WA protruding outward. The tip may be provided such that a lower portion of the partition wall WA is more deeply etched than an upper portion of the partition wall WA.

The first partition layer W1 may have a thickness (e.g., as measured between a top surface of the first partition layer W1 and a bottom surface of the first partition layer W1) greater than that of the second partition layer W2 (e.g., as measured between a top surface of the second partition layer W2 and a bottom surface of the second partition layer W2), and a top surface of the first partition layer W1 may have a surface area smaller than that of a bottom surface of the second partition layer W2. Accordingly, a side surface of the second partition layer W2 may protrude from a side surface of the first partition layer W1 to provide the tip.

The tip may be provided due to a difference in an etching rate for an etching solution between the first partition layer W1 and the second partition layer W2. Accordingly, the tip may be provided by the first partition layer W1 being etched more than the second partition layer W2. The tip may be provided by performing dry etching followed by wet etching.

In embodiments of the inventive concepts, a side surface of the protective layer PA may include at least one tip. A side surface of the third protective layer P3 may protrude from a side surface of the first protective layer P1 or the second protective layer P2 to provide at least one tip. The second protective layer P2 and the third protective layer P3 may be dry-etched, and the first protective layer P1 may be wet-etched. That is, the tip on the protective layer PA may be provided due to a difference in etching rates for an etching solution among the first to third protective layers P1, P2, and P3.

The tip may interrupt a layer deposited in a deposition process. Specifically, when the intermediate layer CL-B is deposited, there may be an uncoated region that is not reached by the deposition material due to the side surface shaded by the tip, that is, a portion having an undercut shape. The intermediate layer CL-B may be disconnected at a side surface of the partition wall WA due to the uncoated region. Accordingly, since the intermediate layers CL-B and CL-G2 disposed in adjacent light-emitting areas PXA-B and PXA-G2 may be disconnected from each other, generation of lateral leakage current between the light-emitting areas PXA-B and PXA-G may be prevented (or reduced).

Since the second electrode CE is also provided through a deposition process, disconnection due to the partition wall WA may occur. However, a deposition angle for the second electrode CE may be differently controlled from that for the intermediate layers CL-B and CL-G2. Accordingly, a deposition material for forming the second electrode CE may also be deposited on a portion of the side surface that is shadowed by the tip. The second electrode CE may cover at least a part of the side surface of the first partition layer W1. Even when the second electrode CE is disconnected between the adjacent light-emitting areas PXA-B and PXA-G2, the second electrode CE may be electrically connected through the partition wall WA. Therefore, a common voltage may be supplied to all of the light-emitting areas PXA-B and PXA-G2 through the second electrode CE.

A dummy pattern CL-P may be disposed on the partition wall WA. The dummy pattern CL-P may be a pattern formed in a process of forming a deposition layer such as the intermediate layer CL-B or CL-G2 or the second electrode CE, and may be separated from portions of the intermediate layer CL-B or CL-G2 or the second electrode CE. Accordingly, the dummy pattern CL-P may include the same material as (or a similar material to) the intermediate layer CL-B or CL-G2 or the second electrode CE, and may be a single layer or multiple layers, and is not limited to any specific example.

Since the second electrode CE is connected to a second power line PL2 (see FIG. 6B) disposed in a display region DA (see FIG. 3) through the partition wall WA and the second conductive pattern 402, a voltage drop phenomenon may be prevented (or reduced) and a constant voltage may be supplied to the pixels. Further, since the connection between the second electrode CE and the second power line PL2 (see FIG. 6b) is made within the display region DA (see FIG. 3), an unnecessary space for connecting the second electrode CE and the second power line PL2 in a non-display region NDA may be reduced. In addition, pixel units having different resolutions may be individually driven.

A cross-sectional shape of the partition wall WA shown in FIG. 9 is merely illustrative of embodiments of the inventive concepts, and the partition wall WA may have a disconnected structure having a reverse-tapered shape or a disconnected structure including a recessed portion in cross section. When disconnection of the intermediate layer CL-B or CL-G2 may occur due to partial non-deposition during deposition of the intermediate layer CL-B or CL-G2, the partition wall WA may have various shapes and is not limited to any specific example.

Referring again to FIGS. 8A and 8B, a thin film encapsulation layer TFE may be disposed on a display element layer DP-OLED to cover a light-emitting element OLED-B. The thin film encapsulation layer TFE may be disposed on the entire display region DA. The thin film encapsulation layer TFE may include inorganic film layers and an organic layer disposed between the inorganic film layers, and is not limited to any particular example. Among the inorganic layers included in the thin film encapsulation layer TFE, a lower inorganic layer may be directly disposed on the second electrode CE and may cover the second electrode CE with a shape corresponding to the second electrode CE.

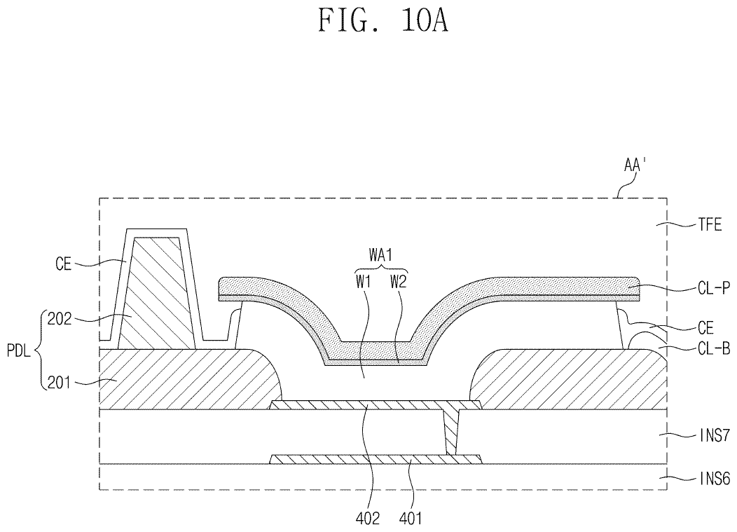

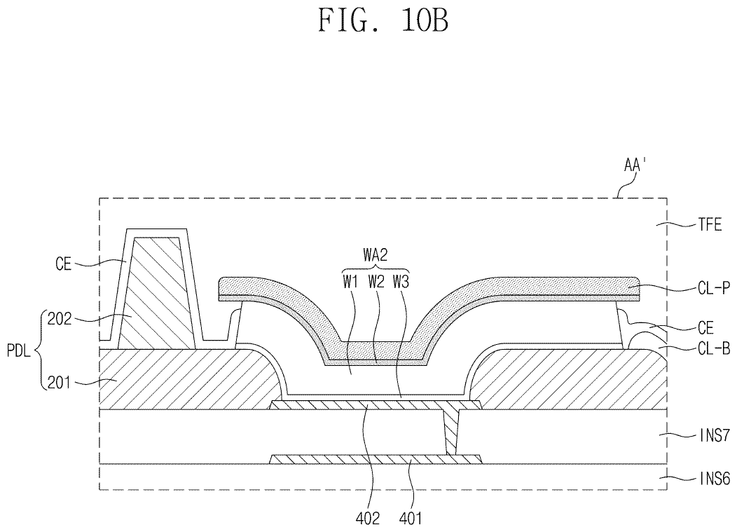

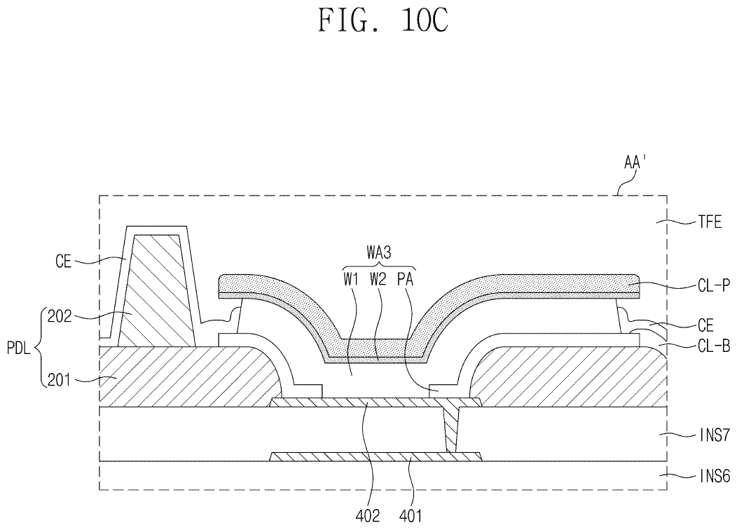

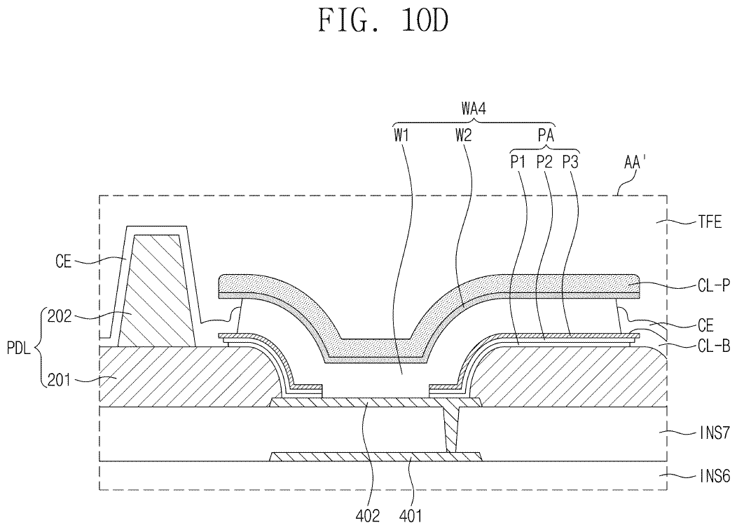

FIGS. 10A to 10D are enlarged views of the display panel according to embodiments of the inventive concepts.

FIGS. 10A to 10D are enlarged views of a portion (AA') illustrated in FIG. 8A. FIGS. 10A to 10D exemplarily illustrate embodiments of the partition wall WA1 disposed in the contact opening C-OP (e.g., the partition wall WA in the portion AA′). The same reference numerals (or similar reference numerals) are assigned to components of the partition wall WA having the same configuration as (or a similar configuration to) those described in FIG. 9, and redundant description will be omitted since the same content (or similar content) may apply.

Referring to FIG. 10A, a partition wall WA1 may have a two-layer structure including a first partition layer W1 and a second partition layer W2. That is, in the partition wall WA1, the third partition layer W3 and the protective layer PA illustrated in FIG. 9 may be omitted. A tip may be defined by a side step difference between the first partition layer W1 and the second partition layer W2.

Alternatively, referring to FIG. 10B, a partition wall WA2 according to embodiments of the inventive concepts may have a three-layer structure including the first to third partition layers W1, W2, and W3. That is, in the partition wall WA2, the protective layer PA illustrated in FIG. 9 may be omitted. Accordingly, the third partition layer W3 may directly contact the pixel defining layer PDL and the second conductive pattern 402. According to the inventive concepts, by omitting the protective layer PA, an etching process for the protective layer PA to establish connection with the second conductive pattern 402 may be omitted, thereby simplifying the overall process.

Alternatively, referring to FIG. 10C, a partition wall WA3 according to embodiments of the inventive concepts may have a three-layer structure including the first partition layer W1, the second partition layer W2, and the protective layer PA. That is, in the partition wall WA3, the third partition layer W3 illustrated in FIG. 9 may be omitted, and the protective layer PA may be a single layer. The protective layer PA may be etched in a region overlapping the contact opening C-OP such that at least a portion of the second conductive pattern 402 is exposed. Accordingly, the second conductive pattern 402 and the first partition layer W1 may be in direct contact with each other.

Alternatively, referring to FIG. 10D, a partition wall WA4 according to embodiments of the inventive concepts may have a five-layer structure including the first partition layer W1, the second partition layer W2, and the first to third protective layers P1, P2, and P3. That is, in the partition wall WA4, the third partition layer W3 illustrated in FIG. 9 may be omitted. The first to third protective layers P1, P2, and P3 may be etched in a region overlapping the contact opening C-OP such that at least a portion of the second conductive pattern 402 is exposed. A tip may be provided by side step difference resulting from etching the first to third protective layers P1, P2, and P3.

The cross-sectional shapes of the partition walls WA illustrated in FIGS. 10A to 10D are examples and are not limited to any one example. When the intermediate layer CL-B is disconnected due to partial non-deposition during deposition and the partition wall WA is electrically connected to the second conductive pattern 402, the partition wall WA may have various shapes and is not limited to any one example.

FIGS. 11A to 11M are cross-sectional views illustrating a method for manufacturing a display panel according to embodiments of the inventive concepts.

FIGS. 11A to 11M sequentially illustrate some of the operations for forming the display panel DP corresponding to the example shown in FIG. 8A. Hereinafter, the inventive concepts will be described with reference to FIGS. 11A to 11M. In the following description, the same reference numerals (or similar reference numerals) are given to components that are the same as (or similar to) those described in FIGS. 6A to 8B, and redundant description will be omitted.

Referring to FIG. 11A, transistors T1, T4, and T6 may be formed on a base substrate SUB. The transistors T1, T4, and T6 may be formed on a barrier layer BRL and a buffer layer BFL formed on the barrier layer BRL. Specifically, a semiconductor layer S1, A1, and Dr1 of a first transistor T1 and a semiconductor layer S6, A6, and Dr6 of a sixth transistor T6 may be formed on the buffer layer BFL. A first insulating layer INS1 may be formed on the buffer layer BFL to cover the semiconductor layers S1, A1, Dr1, S6, A6, and Dr6. A first gate electrode G1 (or a control electrode) of the first transistor T1 and a sixth gate electrode G6 (or a control electrode) of the sixth transistor T6 may be formed on the first insulating layer INS1. A second insulating layer INS2 may be formed on the first insulating layer INS1 to cover the first and sixth gate electrodes G1 and G6. A dummy electrode DME may be formed on the second insulating layer INS2. A third insulating layer INS3 may be formed on the second insulating layer INS2 to cover the dummy electrode DME. Semiconductor layers S4, A4, and Dr4 of a fourth transistor T4 may be formed on the third insulating layer INS3. A fourth insulating layer INS4 may be formed on the third insulating layer INS3 to cover the semiconductor layers S4, A4, and Dr4. A fourth gate electrode G4 of the fourth transistor T4 may be formed on the fourth insulating layer INS4. A fifth insulating layer INS5 may be formed on the fourth insulating layer INS4 to cover the fourth gate electrode G4. A first connection electrode CNE1 connected to the sixth transistor T6 may be formed on the fifth insulating layer INS5. A sixth insulating layer INS6 may be formed on the fifth insulating layer INS5 to cover the first connection electrode CNE1.

Referring to FIG. 11B, a first conductive pattern 401 and a second connection electrode CNE2 may be formed on the transistors T1, T4, and T6. Specifically, the first conductive pattern 401 and the second connection electrode CNE2 may be formed on the sixth insulating layer INS6. The first conductive pattern 401 and the second connection electrode CNE2 may be formed by depositing or coating a conductive material on the sixth insulating layer INS6 and then patterning the conductive material through a single mask. That is, a first conductive pattern 401 and a second connection electrode CNE2 may be formed simultaneously (or contemporaneously) through a single process. However, this is only an illustrative example, and the first conductive pattern 401 and the second connection electrode CNE2 may also be independently formed through different processes, and are not limited to any one example.

Next, referring to FIGS. 11C and 11D, a seventh insulating layer INS7 may be disposed on the first conductive pattern 401. As illustrated in FIG. 11C, an initial organic layer INS7-I may be disposed by applying an organic material onto the first conductive pattern 401. Thereafter, as shown in FIG. 11D, a contact hole CH may be defined by patterning the initial organic layer INS7-I to expose a portion of the first conductive pattern 401, and another contact hole may be defined to expose a portion of the second connection electrode CNE2, so that the seventh insulating layer INS7 may be disposed.

Next, referring to FIG. 11E, a second conductive pattern 402 overlapping the first conductive pattern 401, and a first electrode AE spaced apart from the second conductive pattern 402 may be disposed on the seventh insulating layer INS7. The second conductive pattern 402 and the first electrode AE may be disposed by depositing or coating a conductive material on the seventh insulating layer INS7 and patterning the same through a single mask. That is, the second conductive pattern 402 and the first electrode AE may be disposed simultaneously (or contemporaneously) through a single process. However, this is only an illustrative example, and the second conductive pattern 402 and the first electrode AE may also be independently disposed through different processes, and are not limited to any one example. The second conductive pattern 402 may be formed to fill the contact hole CH and to be connected to the first conductive pattern 401. Similarly, the first electrode AE may be formed to fill a contact hole that exposes the second connection electrode CNE2 and to be connected to the second connection electrode CNE2.

Referring to FIGS. 11F and 11G, an initial pixel defining layer PDL-I may be formed by applying an organic material on the seventh insulating layer INS7. Thereafter, in the initial pixel defining layer PDL-I, a contact opening C-OP, a emission opening PDL-OP, a base layer 201, and a protrusion 202 may be defined using a halftone mask MS to form a pixel defining layer PDL. The base layer 201 and the protrusion 202 may be integrally formed in a single process using the halftone mask MS.

The halftone mask MS may include regions having different transmittance. The halftone mask MS may include a plurality of regions having different amounts of light transmission. For example, as shown in FIG. 11G, the halftone mask MS may include a first region C1, a second region C2, and a third region C3 having different light transmittance. The first region C1 may have the highest light transmittance, and the third region C3 may have the lowest light transmittance. The second region C2 may have a light transmittance higher than that of the third region C3 and lower than that of the first region C1. For example, the first region C1 may transmit about 10% of light. The second region C2 may transmit about 50% of light. The third region C3 may transmit about 90% of light. However, the amount of light transmitted is merely illustrative and is not limited thereto.

A region, which corresponds to the first region C1, of the initial pixel layer PDL-I may receive the least amount of light or may not be irradiated with light. A region, which corresponds to the third region C3, of the initial pixel layer PDL-I may be irradiated with the greatest amount of light, and a region, which corresponds to the second region C2, of the initial pixel layer PDL-I may be irradiated with a smaller amount of light than the third region C3. Subsequently, after a development process, a region corresponding to the third region C3 of the initial pixel defining layer PDL-I may be completely removed to define openings PDL-OP and C-OP, and a region corresponding to the second region C2 may be partially removed to be provided as a base layer 201 having a thickness smaller than that of the initial pixel defining layer PDL-I. The region corresponding to the first region C1 may be scarcely removed and may be formed to have a thickness almost equal to that of the initial pixel defining layer PDL-I. Accordingly, a protrusion 202 protruding from the base layer 201 may be disposed in the region corresponding to the first region C1.

As described above, the protrusion 202 may serve as a spacer. Therefore, an operation of additionally forming a spacer on the pixel defining layer PDL may not be necessary, which simplifies the process and reduces the number of photolithography operations, thereby improving process efficiency.

Next, referring to FIG. 11H, an initial protective layer PA-I may be disposed on the pixel defining layer PDL.

The initial protective layer PA-I may be disposed by sequentially depositing indium gallium zinc oxide, silicon nitride, and silicon oxide on the pixel defining layer PDL. However, this is only an illustrative example and is not limited thereto. In addition, as described above, the protective layer PA may be omitted. Thus, in embodiments in which the partition wall WA does not include the protective layer PA, an operation of forming the initial protective layer PA-I may be omitted.

Referring to FIG. 11I, the initial protective layer PA-I may be etched to expose at least a portion of the second conductive pattern 402, thereby forming a protective layer PA-I2. The protective layer PA-I may be sequentially subjected to dry etching and wet etching. The protective layer PA-I2 may not expose the first electrode AE, thereby having an effect of preventing (or reducing) damage to the first electrode AE during an operation of etching an initial partition wall WA-I described below. However, as described above, the protective layer PA may be omitted. Thus, in embodiments in which the partition wall WA does not include the protective layer PA, an operation of etching the protective layer PA-I2 may be omitted.

Referring to FIG. 11J, an initial partition wall WA-I may be formed on the pixel defining layer PDL. In embodiments in which the partition wall WA includes the protective layer PA, an initial partition wall layer WL-I comprising a plurality of conductive layers may be disposed on the protective layer PA-I2 to dispose the initial partition wall WA-I. However, as described above, the protective layer PA may be omitted. Thus, in embodiments in which the partition wall WA does not include the protective layer PA, the initial partition wall layer WL-I may be disposed on the pixel defining layer PDL to dispose the initial partition wall WA-I. The initial partition wall WA-I may be provided by forming a plurality of conductive layers on the pixel defining layer PDL.

Referring to FIG. 11K, the initial partition wall WA-I may be etched to dispose a partition wall WA. Through the etching process, a portion corresponding to the emission opening PDL-OP may be removed, and portions disposed on the upper surface of the pixel defining layer PDL or on the contact opening C-OP may remain to dispose a first partition wall WA-a (see FIG. 8A) and a second partition wall WA-b (see FIG. 8A). At this point, although not illustrated, a tip of the partition wall WA may be formed through the etching process. Accordingly, the etching process may include at least one dry etching process and at least one wet etching process, and the tip may be formed through a plurality of distinct etching processes. Detailed descriptions thereof are omitted to avoid redundancy. According to embodiments, the tip (e.g., at least one tip) may be formed by the at least one wet etching process.

In embodiments in which the partition wall WA includes the protective layer PA, an operation of etching an initial partition wall WA-I may include an operation of etching an initial partition wall layer WL-I followed by an operation of etching a protective layer PA-I2. The protective layer PA-I2 may be dry-etched and wet-etched to expose at least a portion of the first electrode AE. However, as described above, since the protective layer PA may be omitted, and in embodiments in which the partition wall WA does not include the protective layer PA, the operation of etching the protective layer PA-I2 may be omitted.

Referring to FIG. 11L, intermediate layers CL-B and CL-G2 may be deposited on the first electrode AE. In the process in which the intermediate layers CL-B and CL-G2 are deposited, the intermediate layers CL-B and CL-G2 may be separated from and formed with a dummy pattern CL-P. Since the deposition material is not deposited on a side surface of the partition wall WA, the deposition material formed on the top surface of the partition wall WA may become the dummy pattern CL-P (see FIG. 11M) and be physically separated and disconnected from the deposition layer. Accordingly, even without an additional patterning process using a separate mask, since separated deposition layers may be formed between adjacent light-emitting areas without using a separate mask, the process may be simplified and process cost may be reduced. In addition, since leakage current between the light-emitting areas PXA-G1, PXA-G2, PXA-R, and PXA-B (see FIG. 7A) may be prevented (or reduced), a display panel DP having improved reliability may be provided.

Referring to FIG. 11M, a second electrode CE and a thin film encapsulation layer TFE may be sequentially disposed on the intermediate layers CL-B and CL-G2. The second electrode CE may be deposited on the intermediate layers CL-B and CL-G2. In the process in which the second electrode CE is deposited, the second electrode CE may be separated from the dummy pattern CL-P by the partition wall WA. However, as described above, a deposition angle of the second electrode CE may be controlled to be different from that of the intermediate layers CL-B and CL-G2. Accordingly, the deposition material for forming the second electrode CE may be disposed so as to cover at least a portion of the side surface that is shielded by the tip.

The thin film encapsulation layer TFE may be disposed on the second electrode CE. The thin film encapsulation layer TFE may be disposed as an integrated layer commonly placed on the display panel DP. The thin film encapsulation layer TFE may extend from the light-emitting areas PXA-G1, PXA-G2, PXA-R, and PXA-B (see FIG. 7A) to a non-emission area NPXA, and may be disposed to cover the second electrode CE and the partition wall WA.

According to the electronic device and the method for manufacturing the same, since the separate spacer does not need to be additionally disposed on the partition wall, the process efficiency may be improved.

The electronic device and the method of manufacturing the same of the inventive concepts may allow the second electrode to be connected to the power line through the partition wall and the second conductive pattern, thereby preventing (or reducing) a voltage drop phenomenon and allowing a uniform (or similar) voltage to be supplied to the pixels.

In conventional display devices, light-emitting areas are disconnected from one another, resulting in differences in driving voltages across different light-emitting areas. These differences are particularly prevalent in larger display devices. The differences in driving voltages result in luminance defects that decrease the quality of images displayed by the conventional display devices.

However, according to embodiments, improved display devices are provided. For example, in the improved display devices, light-emitting areas are separated by a partition wall(s) formed of conductive material. Electrodes (e.g., cathodes) of light-emitting elements electrically connect to a power line via the partition wall(s), thereby enabling the electrodes to maintain the same constant voltage (or similar voltages). Accordingly, the improved display devices overcome the deficiencies of the conventional display devices to at least prevent or reduce luminance defects caused by differences in driving voltages, and thus, increase the quality of displayed images.

According to embodiments, operations described herein as being performed by the electronic apparatus DD, the processor 110, the input module 130, the display module DM, the power module 150, the internal module 160, the external module 170, the main processor 111, the auxiliary processor 112, the central processing unit 111-1, the application processor (AP), the graphic processing unit 111-2, the communication processor (CP), the image signal processor (ISP), the neural processing unit 111-3, the controller 112-1, the data conversion circuit 112-2, the gamma correction circuit 112-3, the rendering circuit 112-4, the external electronic device 102, the input module 130, the first input module 131, the second input module 132, the display panel DP, the scan driver SDC, the data driver DDV, the sensor module 161, the antenna module 162, the sound output module 163, the fingerprint sensor 161-1, the input sensor 161-2, the digitizer 161-3, the camera module 171, the light module 172, the communication module 173, the touch pen PEN, the timing controller T-C, the light emission driver EDV, and/or the voltage generator VG may be performed by processing circuitry. The term ‘processing circuitry,’ as used in the present disclosure, may refer to, for example, hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), a digital signal processor, a microcomputer, a field programmable gate array (FPGA), a System-on-Chip (SoC), a programmable logic unit, a microprocessor, application-specific integrated circuit (ASIC), etc.

The various operations of methods described above may be performed by any suitable device capable of performing the operations, such as the processing circuitry discussed above. For example, as discussed above, the operations of methods described above may be performed by various hardware and/or software implemented in some form of hardware (e.g., processor, ASIC, etc.).

The software may comprise an ordered listing of executable instructions for implementing logical functions, and may be embodied in any “processor-readable medium” for use by or in connection with an instruction execution system, apparatus, or device, such as a single or multiple-core processor or processor-containing system.

The blocks or operations of a method or algorithm, and/or functions, described in connection with embodiments disclosed herein may be embodied directly in hardware, in a software module executed by a processor, or in a combination of the two. If implemented in software, the functions may be stored on or transmitted over as one or more instructions or code on a tangible, non-transitory computer-readable medium. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD ROM, or any other form of storage medium known in the art.

Although the present disclosure has been described with reference to embodiments, it will be understood that various changes and modifications of the present disclosure may be made by one ordinary skilled in the art or one having ordinary knowledge in the art without departing from the spirit and technical field of the disclosure as hereinafter claimed.

Hence, the technical scope of the inventive concepts shall be determined by the technical scope of the accompanying claims.

What is claimed is:

1. An electronic device comprising:
a window module; and
a display panel, the window module being on the display panel, and the display panel including,
a base substrate,
a circuit element layer including,
a power line on the base substrate,
an organic insulating layer on the power line,
a transistor between the base substrate and the organic insulating layer, and
a first conductive pattern spaced apart from the transistor and connected to the power line,
a pixel defining layer on the circuit element layer, the pixel defining layer forming an emission opening and a contact opening spaced apart from the emission opening,
a light-emitting element on the circuit element layer, the light-emitting element including,
a first electrode electrically connected to the transistor and at least partially exposed by the emission opening,
a second electrode on the first electrode, and
an intermediate layer between the first electrode and the second electrode,
a second conductive pattern between the organic insulating layer and the pixel defining layer, the second conductive pattern being spaced apart from the first electrode and at least partially exposed by the contact opening, and the second conductive pattern penetrating through the organic insulating layer and connecting to the first conductive pattern, and
a partition wall including a first partition wall in the contact opening and connecting the second electrode to the second conductive pattern.

2. The electronic device of claim 1, wherein
the partition wall includes,
a second partition wall overlapping the pixel defining layer; and
the first partition wall and the second partition wall are connected to each other to have an integrated shape.

3. The electronic device of claim 1, wherein a side surface of the partition wall includes at least one first tip.

4. The electronic device of claim 3, wherein
the partition wall includes a first partition wall layer and a second partition wall layer on the first partition wall layer; and
the at least one first tip is defined by a side surface of the second partition wall layer that protrudes from a side surface of the first partition wall layer.

5. The electronic device of claim 4, wherein the partition wall includes a third partition wall layer below the first partition wall layer.

6. The electronic device of claim 4, wherein the first partition wall layer is conductive.

7. The electronic device of claim 4, wherein the intermediate layer is spaced apart from the second partition wall layer in a planar view.

8. The electronic device of claim 6, wherein the second electrode is in contact with the first partition wall layer.

9. The electronic device of claim 4, wherein the partition wall includes a protective layer between the pixel defining layer and the first partition wall layer.

10. The electronic device of claim 9, wherein a side surface of the protective layer includes at least one second tip.

11. The electronic device of claim 10, wherein
the protective layer includes a first protective layer, a second protective layer, and a third protective layer sequentially laminated; and
the at least one second tip is defined by a side surface of the third protective layer that protrudes from a side surface of the first protective layer or a side surface of the second protective layer.

12. The electronic device of claim 11, wherein
the first protective layer includes a metal oxide; and
the second protective layer and the third protective layer include insulating materials.

13. The electronic device of claim 1, further comprising at least one of a processor, a memory, or a power module.

14. The electronic device of claim 1, wherein the electronic device is a television, a monitor, an outdoor signboard, a personal computer, a notebook computer, a personal digital terminal, an automotive instrument panel, a center fascia, a navigation device, a room mirror display, a game console, a smartphone, a tablet, a smart watch, smart glasses, a head-mounted display, or a camera.

15. An electronic device comprising:
a window module; and
a display panel, the window module being on the display panel, and the display panel including,
a base substrate,
a circuit element layer including,
a power line on the base substrate,
an organic insulating layer on the power line,
a transistor between the base substrate and the organic insulating layer, and
a first conductive pattern spaced apart from the transistor and connected to the power line,
a pixel defining layer on the circuit element layer, the pixel defining layer forming an emission opening and a contact opening spaced apart from the emission opening, and the pixel defining layer including,
a base layer in which the emission opening and the contact opening are defined; and
a protrusion spaced apart from the emission opening in a planar view and protruding upward from the base layer,
a light-emitting element on the circuit element layer, the light-emitting element including,
a first electrode electrically connected to the transistor and at least partially exposed by the emission opening,
a second electrode on the first electrode, and
an intermediate layer between the first electrode and the second electrode, and
a partition wall in the contact opening and electrically connecting the first conductive pattern to the second electrode, the partition wall being on the base layer, and a top surface of the partition wall being spaced apart from a top surface of the protrusion in the planar view.

16. The electronic device of claim 15, wherein the base layer and the protrusion have an integrated shape.

17. The electronic device of claim 15, further comprising:
a second conductive pattern at a same layer as the first electrode,
wherein the second conductive pattern is connected to the partition wall through the contact opening and penetrates through the organic insulating layer to connect to the first conductive pattern.

18. A method for manufacturing an electronic device, the method comprising:
forming a transistor on a base substrate;
forming a first conductive pattern on the transistor;
forming a first organic insulating layer on the first conductive pattern;
forming a contact hole in the first organic insulating layer to expose at least a portion of the first conductive pattern;
forming a second conductive pattern and a first electrode on the first organic insulating layer, the second conductive pattern being connected to the first conductive pattern through the contact hole, and the first electrode being spaced apart from the second conductive pattern;
applying an organic material on the first organic insulating layer to form an initial pixel defining layer;
forming a pixel defining layer using a halftone mask on the initial pixel defining layer, the pixel defining layer including a base layer and a protrusion;
forming a plurality of conductive layers on the pixel defining layer;
etching the conductive layers to form a partition wall;
depositing an intermediate layer on the first electrode; and
depositing a second electrode on the intermediate layer.

19. The method of claim 18, wherein
the etching of the plurality of conductive layers includes dry etching and wet etching; and
at least one tip is formed on a side surface of the partition wall by the wet etching.

20. The method of claim 18, further comprising:
forming a second organic insulating layer covering the transistor,
wherein the forming of the first conductive pattern includes forming the first conductive pattern on the second organic insulating layer.
